(19) United States
(12) Patent Application Publication
(10) Pub. No.: US 2022/0324698 A1
(43) Pub. Date: Oct. 13, 2022

(54) PHOTOCURRENT NOISE SUPPRESSION FOR MIRROR ASSEMBLY

(71) Applicant: Beijing Voyager Technology Co., Ltd., Beijing (CN)

(72) Inventors: Sergio Fabien Almeida Loya, Mountain View, CA (US); Youmin Wang, Mountain View, CA (US)

(21) Appl. No.: 17/224,940

(22) Filed: Apr. 7, 2021

(51) Int. Cl. B81B 3/00; G01S 17/931; G02B 26/08; B81C 1/00; G01S 7/481

(52) U.S. Cl. CPC B81B 3/0083; B81B 3/0018; G01S 17/931; G02B 26/0833; B81C 1/00317; B81C 1/00166; B81C 1/00039; G01S 7/4817; B81B 2201/042; B81B 2203/04; B81C 2201/0166; B81C 2201/0132

(57) ABSTRACT

In one example, an apparatus comprises a semiconductor integrated circuit, the semiconductor integrated circuit including a microelectromechanical system (MEMS) device layer and a silicon substrate, the MEMS layer including at least one micro-mirror assembly, the at least one micro-mirror assembly including a micro-mirror and electrodes. The at least one micro-mirror assembly further includes a light reduction layer formed below a surface of the silicon substrate. A method of fabricating the semiconductor integrated circuit is also provided.

### CROSS-REFERENCES PARAGRAPH FOR RELATED APPLICATIONS

The following regular U.S. patent applications (including this one) are being filed concurrently, and the entire disclosure of the other applications are incorporated by reference into this application for all purposes:
Application No. ______, filed ______, entitled “PHOTOCURRENT NOISE SUPPRESSION FOR MIRROR ASSEMBLY” (Attorney Docket No. 103343-1223928-006900US);
Application No. ______, filed ______, entitled “PHOTOCURRENT NOISE SUPPRESSION FOR MIRROR ASSEMBLY” (Attorney Docket No. 103343-1225056-006910US); and
Application No. ______, filed ______, entitled “ PHOTOCURRENT NOISE SUPPRESSION FOR MIRROR ASSEMBLY ” (Attorney Docket No. 103343-1225057-006920US).

### BACKGROUND

Light steering typically involves the projection of light in a predetermined direction to facilitate, for example, the detection and ranging of an object, the illumination and scanning of an object, or the like. Light steering can be used in many different fields of applications, including, for example, autonomous vehicles and medical diagnostic devices.

Light steering can be performed in both transmission and reception of light. For example, a light steering system may include a micro-mirror array to control the projection direction of light to detect/image an object. Moreover, a light steering receiver may also include a micro-mirror array to select a direction of incident light to be detected by the receiver to avoid detecting other unwanted signals. The micro-mirror array may include an array of micro-mirror assemblies, with each micro-mirror assembly comprising a micro-mirror and an actuator. In a micro-mirror assembly, a micro-mirror can be connected to a substrate via a connection structure (e.g., a torsion bar, a spring) to form a pivot, and the micro-mirror can be rotated around the pivot by the actuator. Each micro-mirror can be rotated by a rotation angle to reflect (and steer) light from a light source towards a target direction. Each micro-mirror can be rotated by the actuator to provide a first range of angles of projection along a vertical axis and to provide a second range of angles of projection along a horizontal axis. The first range and the second range of angles of projection can define a two-dimensional field of view (FOV) in which light is to be projected to detect/scan an object. The FOV can also define the direction of incident lights, reflected by the object, to be detected by the receiver.

Ideally, all micro-mirror assemblies of a micro-mirror array are identical, and the micro-mirror in each micro-mirror assembly can be controlled to rotate uniformly by a target rotation angle in response to a control signal. However, due to variations in the fabrication process, as well as other non-idealities, the control precision of the micro-mirror may become degraded, such that a micro-mirror of a micro-mirror assembly may not rotate by the exact target rotation angle in response to the control signal. Moreover, different micro-mirrors of the micro-mirror array may rotate by different angles in response to the same control signal. All these can degrade the uniformity of the rotations among the micro-mirrors. Therefore, it is desirable to improve the control precision of the micro-mirror to improve the uniformity of rotations among the micro-mirrors.

### BRIEF SUMMARY

In some examples, an apparatus is provided. The apparatus comprises a light detection and ranging (LiDAR) module. The LiDAR module includes: a semiconductor integrated circuit, the semiconductor integrated circuit including a microelectromechanical system (MEMS) device layer, an oxide layer, and a silicon substrate, the oxide layer being sandwiched between the MEMS device layer and the silicon substrate, the MEMS device layer including at least one micro-mirror assembly, the at least one micro-mirror assembly including: a micro-mirror comprising a reflective surface, the micro-mirror being coupled with mirror anchors on the oxide layer at a pair of pivot points, the reflective surface being configured to reflect incident light; and electrodes coupled with electrode anchors on the oxide layer and controllable to rotate the micro-mirror around the pair of pivot points to set a direction of reflection of the incident light by the reflective surface. The at least one micro-mirror assembly further includes a light reduction layer between at least a part of the MEMS device layer and the oxide layer.

In some aspects, the mirror anchors are formed on the light reduction layer. At least some of the electrode anchors are formed on the oxide layer.

In some aspects, the electrode anchors include first electrode anchors and second electrode anchors. The first electrode anchors are formed on the oxide layer. The second electrode anchors are formed on the light reduction layer.

In some aspects, the light reduction layer includes a semiconductor material.

In some aspects, the light reduction layer is configured to generate charge upon receiving the at least part of the incident light. The apparatus further comprises a current sink electrically coupled with the light reduction layer to conduct the charge away from the light reduction layer.

In some aspects, the light reduction layer is doped with an N-type or P-type dopant.

In some aspects, the micro-mirror comprises first rotary electrodes and second rotary electrodes. The apparatus comprises first stator electrodes and second stator electrodes formed as the electrodes on the electrode anchors. The first rotary electrodes interdigitate with the first stator electrodes to form a first actuator. The second rotary electrodes interdigitate with the second stator electrodes to form a second actuator. The light reduction layer is operable to block at least some of the incident light that pass through gaps between the first stator electrodes and the first rotary electrodes and gaps between the second stator electrodes and the second rotary electrodes from penetrating into the silicon substrate.

In some aspects, the apparatus further comprises a measurement circuit configured to: apply a first voltage at the first stator electrodes; measure a second voltage between the first stator electrodes and the first rotary electrodes; and determine an actual rotation angle of the micro-mirror based on the second voltage.

In some aspects, the second voltage is based on the first voltage, a first capacitance between the first stator electrodes and the first rotary electrodes, a second capacitance between the anchor electrodes and the silicon substrate, and a third capacitance between the first stator electrodes and the silicon substrate. The light reduction layer is configured to reduce a quantity of charge generated by the silicon substrate in response to the at least part of the incident light and accumulated at the second capacitance and the third capacitance.

In some aspects, the apparatus further includes a controller configured to apply a third voltage between the first stator electrodes and the first rotary electrodes, and a fourth voltage between the second stator electrodes and the second rotary electrodes, to rotate the micro-mirror by a target rotation angle. The first voltage comprises an AC voltage at a first frequency. The third and fourth voltages comprise AC voltages at a second frequency. The second frequency is lower than the first frequency.

In some aspects, the controller is configured to: determine a difference between the target rotation angle and the actual rotation angle; and adjust the third and fourth voltages based on the difference.

In some aspects, the MEMS device layer comprises an array of micro-mirror assemblies. The controller is configured to generate a voltage for the electrodes of a second micro-mirror assembly of the array of micro-mirror assemblies based on the actual rotation angle of the micro-mirror of the at least one micro-mirror assembly.

In some examples, a method of fabricating a micro-mirror assembly of a Light Detection and Ranging (LiDAR) module is provided. The method comprises: patterning a first silicon substrate of a silicon-on-insulator (SOI) wafer to form a first region corresponding to at least some of electrode anchors and a second region corresponding to an light reduction layer, the SOI wafer comprising the first silicon substrate, a second silicon substrate, and an oxide layer sandwiched between the first silicon substrate and the second silicon substrate; patterning the second region of the first silicon substrate to form mirror anchors on a light reduction layer, the mirror anchors being formed on the light reduction layer; bonding a silicon wafer onto the electrode anchors and the mirror anchors; and patterning the silicon wafer to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

In some aspects, the electrode anchors include first electrode anchors and second electrode anchors. The first region of the first silicon substrate corresponds to the first electrode anchors. The second region of the first silicon substrate is patterned to form the second electrode anchors on the light reduction layer.

In some aspects, the first silicon substrate is patterned using a first deep reactive-ion (DRIE) etching operation that stops at the oxide layer.

In some aspects, the second region of the first silicon substrate is patterned using a second DRIE etching operation. A depth of the second DRIE etching operation is based on a dimension of the micro-mirror and a range of rotation angles of the micro-mirror around the pair of pivot points.

In some aspects, the silicon wafer is bonded onto the first electrode anchors, the second electrode anchors, and the mirror anchors via a wafer-bonding operation.

In some aspects, the electrodes include first stator electrodes and second stator electrodes coupled with the electrode anchors. The micro-mirror further includes first rotary electrodes and second rotary electrodes. The first rotary electrodes interdigitate with the first stator electrodes to form a first actuator. The second rotary electrodes interdigitate with the second stator electrodes to form a second actuator. The method further comprises: coating a layer of metal over a first part of the micro-mirror to form a reflective surface; and coating a layer of anti-reflection material over a second part of the micro-mirror corresponding to the first rotary electrodes and the second rotary electrodes, and over the first stator electrodes and the second stator electrodes.

In some aspects, the method further comprises: after coating the layer of metal and the layer of anti-reflection material, performing a third DRIE etching operation to form the micro-mirror and the first stator electrodes, and the second stator electrodes.

In some aspects, the method further comprises: forming electrical contacts on the first silicon substrate; and forming metallic wires that electrically couple the electrical contacts with the light reduction layer, the electrodes, and the micro-mirror.

In some examples, a micro-mirror assembly is provided. The micro-mirror assembly is fabricated by a process comprising: patterning a first silicon substrate of a silicon-on-insulator (SOI) wafer to form a first region corresponding to first electrode anchors and a second region corresponding to an light reduction layer, the SOI wafer comprising a first silicon substrate, a second silicon substrate, and an oxide layer sandwiched between the first silicon substrate and the second silicon substrate; patterning the second region of the first silicon substrate to form second electrode anchors and mirror anchors on the light reduction layer; bonding a silicon wafer onto the first electrode anchors, the second electrode anchors, and the mirror anchors; and patterning the silicon wafer to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

In some examples, an apparatus is provided. The apparatus comprises a light detection and ranging (LiDAR) module, the LiDAR module including: a semiconductor integrated circuit, the semiconductor integrated circuit including a microelectromechanical system (MEMS) device layer and a silicon substrate, the MEMS device layer including at least one micro-mirror assembly. The at least one micro-mirror assembly includes: a micro-mirror comprising a reflective surface, the micro-mirror being coupled with mirror anchors on the silicon substrate at a pair of pivot points, the reflective surface being configured to reflect incident light; and electrodes coupled with electrode anchors on the silicon substrate and controllable to rotate the micro-mirror around the pair of pivot points to set a direction of reflection of the incident light by the reflective surface. The at least one micro-mirror assembly of the array of micro-mirror assemblies further includes a light reduction layer on the silicon substrate.

In some aspects, the light reduction layer forms a roughened surface of the silicon substrate, the roughened surface being configured to convert the at least part of the incident light to heat.

In some aspects, the light reduction layer is configured to reflect the at least part of the incident light away from the silicon substrate.

In some aspects, the light reduction layer includes a reflective layer sandwiched between two insulator layers.

In some aspects, the reflective layer comprises a metal layer or a silicon layer.

In some aspects, the insulator layers comprise oxide layers.

In some aspects, the electrodes comprise first rotary electrodes and second rotary electrodes of the micro-mirror, and first stator electrodes and second stator electrodes formed on the electrode anchors. The first rotary electrodes interdigitate with the first stator electrodes to form a first actuator. The second rotary electrodes interdigitate with the second stator electrodes to form a second actuator.

In some aspects, the apparatus further comprises a measurement circuit configured to: apply a first voltage at the first stator electrodes; measure a second voltage between the first stator electrodes and the first rotary electrodes; and determine an actual angle of rotation of the micro-mirror based on the second voltage.

In some aspects, the second voltage is based on the first voltage, a first capacitance between the first stator electrodes and the first rotary electrodes, a second capacitance between the anchor electrodes and the silicon substrate, and a third capacitance between the first stator electrodes and the silicon substrate. The light reduction layer is configured to reduce a quantity of charge generated by the silicon substrate in response to the at least part of the incident light and accumulated at the second capacitance and the third capacitance.

In some aspects, the apparatus further comprises a controller configured to: apply a third voltage between the first stator electrodes and the first rotary electrodes, and a fourth voltage between the second stator electrodes and the second rotary electrodes, to rotate the micro-mirror by a target rotation angle. The first voltage comprises an AC voltage at a first frequency. The third and fourth voltages comprise AC voltages at a second frequency. The second frequency is lower than the first frequency.

In some aspects, the controller is configured to: determine a difference between the target rotation angle and the actual rotation angle; and adjust the third and fourth voltages based on the difference.

In some examples, a method of fabricating a micro-mirror assembly of a Light Detection and Ranging (LiDAR) module is provided. The method comprises: patterning a first silicon substrate of a silicon-on-insulator (SOI) wafer to form electrode anchors and mirror anchors, the SOI wafer comprising the first silicon substrate, a second silicon substrate, and an oxide layer sandwiched between the first silicon substrate and the second silicon substrate, the electrode anchors and mirror anchors being formed on the oxide layer; removing a part of the oxide layer not covered by the electrode anchors and mirror anchors to expose a part of the second silicon substrate; forming a light reduction layer on the part of the second silicon substrate; bonding a silicon wafer onto the electrode anchors and the mirror anchors; and patterning the silicon wafer to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

In some aspects, the light reduction layer is formed based on performing a dry etching operation on the exposed part of the second silicon substrate to form roughened surface on the part of the second silicon substrate.

In some aspects, the dry etching operation is performed after the silicon wafer is patterned to form the light reduction layer under gaps between the micro-mirror and the electrodes.

In some aspects, the light reduction layer comprises a stack of layers, the stack of layers including a reflective layer sandwiched by two insulator layers on the part of the second silicon substrate.

In some aspects, the method further comprises: covering the first silicon substrate with a layer of photoresist; patterning the layer of photoresist to form a patterned layer of photoresist that covers regions of the first silicon substrate corresponding to the mirror anchors and the electrode anchors; after the first silicon substrate is patterned according to the patterned layer of photoresist, depositing the stack of layers on the patterned layer of photoresist and on the exposed part of the second silicon substrate; and performing a lift-off operation to remove the stack of layers deposited on the mirror anchors and the electrode anchors based on removing the patterned layer of photoresist.

In some aspects, the first silicon substrate is patterned, based on the patterned layer of photoresist, using a first deep reactive-ion (DRIE) etching operation that stops at the oxide layer, followed by an oxide etching operation to remove the part of the oxide layer.

In some aspects, the silicon wafer is bonded onto the electrode anchors and the mirror anchors via a wafer-bonding operation.

In some aspects, the electrodes include first stator electrodes and second stator electrodes coupled with the electrode anchors. The micro-mirror further includes first rotary electrodes and second stator electrodes. The first rotary electrodes interdigitate with the first stator electrodes to form a first comb drive actuator. The second rotary electrodes interdigitate with the second stator electrodes to form a second comb drive actuator. The method further comprises: coating a layer of metal over a first part of the micro-mirror to form a reflective surface; and coating a layer of anti-reflection material over a second part of the micro-mirror corresponding to the first rotary electrodes and the second rotary electrodes and over the first stator electrodes and the second stator electrodes.

In some examples, a micro-mirror assembly is provided. The micro-mirror assembly is fabricated by a process comprising: patterning a first silicon substrate of a silicon-on-insulator (SOI) wafer to form electrode anchors and mirror anchors, the SOI wafer comprising a first silicon substrate, a second silicon substrate, and an oxide layer sandwiched between the first silicon substrate and the second silicon substrate, the electrode anchors and mirror anchors being formed on the oxide layer; removing a part of the oxide layer not covered by the electrode anchors and mirror anchors to expose a part of the second silicon substrate; forming a light reduction layer on the exposed part of the second silicon substrate; bonding a silicon wafer onto the electrode anchors and the mirror anchors; and patterning the silicon wafer to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

In some examples, an apparatus is provided. The apparatus comprises a light detection and ranging (LiDAR) module, the LiDAR module including: a semiconductor integrated circuit, the semiconductor integrated circuit including a microelectromechanical system (MEMS) device layer and a silicon substrate, the MEMS device layer including at least one micro-mirror assembly. The at least one micro-mirror assembly includes: a micro-mirror comprising a reflective surface, the micro-mirror being coupled with mirror anchors on the silicon substrate at a pair of pivot points, the reflective surface being configured to reflect incident light; and electrodes coupled with electrode anchors on the silicon substrate and controllable to rotate the micro-mirror around the pair of pivot points to set a direction of reflection of the incident light by the reflective surface. The at least one micro-mirror assembly further includes a light reduction layer formed below a surface of the silicon substrate.

In some aspects, the light reduction layer has a higher dopant concentration than a part of the silicon substrate around and below the light reduction layer.

In some aspects, the light reduction layer is doped with an N-type or a P-type dopant. The rest of the silicon substrate is not doped with any dopant.

In some aspects, both the light reduction layer and the rest of the silicon substrate are doped with an N-type or a P-type dopant.

In some aspects, the light reduction layer is below gaps between the micro-mirror and the electrodes.

In some aspects, the apparatus further comprises an oxide layer sandwiched between each of the mirror anchors and electrode anchors and the silicon substrate.

In some aspects, the electrodes comprise first rotary electrodes and second rotary electrodes of the micro-mirror, and first stator electrodes and second stator electrodes formed on the electrode anchors. The first rotary electrodes interdigitate with the first stator electrodes to form a first actuator. The second rotary electrodes interdigitate with the second stator electrodes to form a second actuator.

In some aspects, the apparatus further comprises a measurement circuit configured to: apply a first voltage at the first stator electrodes; measure a second voltage between the first stator electrodes and the first rotary electrodes; and determine an actual angle of rotation of the micro-mirror based on the second voltage.

In some aspects, the second voltage is based on the first voltage, a first capacitance between the first stator electrodes and the first rotary electrodes, a second capacitance between the mirror anchors and the silicon substrate, and a third capacitance between the first stator electrodes and the silicon substrate. The light reduction layer is configured to reduce a quantity of charge generated by the silicon substrate in response to receiving the at least part of the incident light and accumulated at the second capacitance and the third capacitance.

In some aspects, the apparatus further comprises a controller configured to apply a third voltage between the first stator electrodes and the first rotary electrodes, and a fourth voltage between the second stator electrodes and the second rotary electrodes, to rotate the micro-mirror by a target rotation angle. The first voltage comprises an AC voltage at a first frequency. The third and fourth voltages comprise AC voltages at a second frequency. The second frequency is lower than the first frequency.

In some aspects, the controller is configured to: determine a difference between the target rotation angle and the actual rotation angle; and adjust the third and fourth voltages based on the difference.

In some examples, a method of fabricating a micro-mirror assembly of a Light Detection and Ranging (LiDAR) module is provided. The method comprises: patterning a first silicon substrate of a silicon-on-insulator (SOI) wafer to form electrode anchors and mirror anchors, the SOI wafer comprising a first silicon substrate, a second silicon substrate, and an oxide layer sandwiched between the first silicon substrate and the second silicon substrate, the electrode anchors and mirror anchors being formed on the oxide layer; removing a part of the oxide layer not covered by the electrode anchors and mirror anchors to expose a part of the second silicon substrate; forming a light reduction layer below a surface of the exposed part of the second silicon substrate; bonding a silicon wafer onto the electrode anchors and the mirror anchors; and patterning the silicon wafer to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

In some aspects, the light reduction layer is formed based on performing an ion implantation operation on the part of the second silicon substrate to form the light reduction layer below the surface of the part of the second silicon substrate.

In some aspects, the method further comprises: covering the first silicon substrate with a layer of photoresist; patterning the layer of photoresist to form a patterned layer of photoresist that covers regions of the first silicon substrate corresponding to the mirror anchors and the electrode anchors; and after the first silicon substrate is patterned according to the patterned layer of photoresist, performing the ion implantation operation.

In some aspects, the ion implantation operation is performed after the silicon wafer is patterned to form the light reduction layer under gaps between the micro-mirror and the electrodes.

In some aspects, the first silicon substrate is patterned, based on the patterned layer of photoresist, using a first deep reactive-ion (DRIE) etching process that stops at the oxide layer, followed by an oxide etching process to remove the part of the oxide layer.

In some aspects, the silicon wafer is bonded onto the electrode anchors and the mirror anchors via a wafer-bonding operation.

In some aspects, the electrodes include first stator electrodes and second stator electrodes coupled with the electrode anchors. The micro-mirror further includes first rotary electrodes and second stator electrodes. The first rotary electrodes interdigitate with the first stator electrodes to form a first actuator. The second rotary electrodes interdigitate with the second stator electrodes to form a second actuator. The method further comprises: coating a layer of metal over a first part of the micro-mirror to form a reflective surface; and coating a layer of anti-reflection material over a second part of the micro-mirror corresponding to the first rotary electrodes and the second rotary electrodes and over the first and second stator electrodes.

In some aspects, the method further comprises: after coating the layer of metal and the layer of anti-reflection material, performing a third DRIE etching process to form the micro-mirror and the first and second stator electrodes.

In some examples, a micro-mirror assembly is provided. The micro-mirror assembly is fabricated by a process comprising: patterning a first silicon substrate of a silicon-on-insulator (SOI) wafer to form electrode anchors and mirror anchors, the SOI wafer comprising a first silicon substrate, a second silicon substrate, and an oxide layer sandwiched between the first silicon substrate and the second silicon substrate, the electrode anchors and mirror anchors being formed on the oxide layer; removing a part of the oxide layer not covered by the electrode anchors and mirror anchors to expose a part of the second silicon substrate; forming a light reduction layer below a surface of the part of the second silicon substrate; bonding a silicon wafer onto the electrode anchors and the mirror anchors; and patterning the silicon wafer to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

### BRIEF DESCRIPTION OF THE DRAWINGS

The detailed description is set forth with reference to the accompanying figures.

FIG. 1 shows an autonomous driving vehicle utilizing aspects of certain embodiments of the disclosed techniques herein.

FIG. 2A, FIG. 2B, FIG. 2C, FIG. 2D, and FIG. 2E illustrate examples of a light steering system, according to examples of the present disclosure.

FIG. 3A, FIG. 3B, FIG. 3C, FIG. 3D, and FIG. 3E illustrate other examples of a light steering system and its operation, according to examples of the present disclosure.

FIG. 4 illustrate example techniques to improve the accuracy of rotation angle sensing of a micro-mirror assembly, according to examples of the present disclosure.

FIG. 5A and FIG. 5B illustrate examples of a micro-mirror assembly including techniques to improve the accuracy of rotation angle sensing, according to examples of the present disclosure.

FIG. 6, FIG. 7A, and FIG. 7B illustrate examples of a fabrication process for the example micro-mirror assembly of FIG. 5A and FIG. 5B.

FIG. 8 illustrates examples of a micro-mirror assembly including techniques to improve the accuracy of rotation angle sensing, according to examples of the present disclosure.

FIG. 9, FIG. 10A, and FIG. 10B illustrate examples of a fabrication process for the example micro-mirror assembly of FIG. 8.

FIG. 11 illustrates examples of a micro-mirror assembly including techniques to improve the accuracy of rotation angle sensing, according to examples of the present disclosure.

FIG. 12, FIG. 13A, and FIG. 13B illustrate examples of a fabrication process for the example micro-mirror assembly of FIG. 11.

FIG. 14 illustrates examples of a micro-mirror assembly including techniques to improve the accuracy of rotation angle sensing, according to examples of the present disclosure.

FIG. 15, FIG. 16A, and FIG. 16B illustrate examples of a fabrication process for the example micro-mirror assembly of FIG. 14.

### DETAILED DESCRIPTION

In the following description, various examples of an adaptive control system of a micro-mirror array will be described. The adaptive control system can adjust the control signals for each micro-mirror of the array based on a measurement of an instantaneous rotation angle of the micro-mirror, and a difference (if any) between the instantaneous rotation angle and the target rotation angle of the micro-mirror. For purposes of explanation, specific configurations and details are set forth to provide a thorough understanding of the embodiments. However, it will be apparent to one skilled in the art that certain embodiments may be practiced or implemented without every detail disclosed. Furthermore, well-known features may be omitted or simplified to prevent any obfuscation of the novel features described herein.

Light steering can be found in different applications. For example, a light detection and ranging (LiDAR) module of a vehicle may include a light steering system. The light steering system can be part of the transmitter to steer light towards different directions to detect obstacles around the vehicle and to determine the distances between the obstacles and the vehicle, which can be used for autonomous driving. Moreover, a receiver may also include a micro-mirror array to select a direction of incident light to be detected by the receiver to avoid detecting other unwanted signals. Further, the headlight of a manually driven vehicle can include the light steering system, which can be controlled to focus light towards a particular direction to improve visibility for the driver. In another example, optical diagnostic equipment, such as an endoscope, can include a light steering system to steer light in different directions onto an object in a sequential scanning process to obtain an image of the object for diagnosis.

Light steering can be implemented by way of a micro-mirror array. The micro-mirror array can have an array of micro-mirror assemblies, with each micro-mirror assembly having a movable micro-mirror and an actuator (or multiple actuators). The micro-mirrors and actuators can be formed as microelectromechanical systems (MEMS) on a semiconductor substrate, which allows integration of the MEMS with other circuitries (e.g., controller, interface circuits) on the semiconductor substrate. In a micro-mirror assembly, a micro-mirror can be connected to the semiconductor substrate via a pair of connection structures (e.g., a torsion bar, a spring) to form a pair of pivots. The actuator can rotate the micro-mirror around the pair of pivots, with the connection structure deformed to accommodate the rotation. The array of micro-mirrors can receive an incident light beam, and each micro-mirror can be rotated at a common rotation angle to project/steer the incident light beam at a target direction. Each micro-mirror can be rotated around two orthogonal axes to provide a first range of angles of projection along a vertical dimension and to provide a second range of angles of projection along a horizontal dimension. The first range and the second range of angles of projection can define a two-dimensional FOV in which light is to be projected to detect/scan an object. The FOV can also define the direction of incident lights, reflected by the object, that are to be detected by the receiver.

Compared with using a single mirror to steer the incident light, a micro-mirror array can provide a comparable, or even larger, aggregate reflective surface area. With a larger reflective surface area, incident light with a larger beam width can be projected onto the micro-mirror array for the light steering operation, which can mitigate the effect of dispersion and can improve the imaging/ranging resolution. Moreover, each individual micro-mirror has a smaller size and mass, which can lessen the burdens on the actuators that control those micro-mirrors and can improve reliability. Further, the actuators can rotate the micro-mirrors by a larger rotation angle for a given torque, which can improve the FOV of the micro-mirror array.

For both single-mirror and micro-mirror array, the control precision can substantially affect their performances. Specifically, an actuator may receive a control signal designed to rotate a mirror (or a micro-mirror) by a target rotation angle, but due to limited control precision, the actuator may be unable to rotate the mirror exactly by that target rotation angle. As a result, the mirror may be unable to rotate over a desired range of angle, which can reduce the achievable FOV. Moreover, due to the limited control precision, the rotation angles of each micro-mirror in the array also vary. The non-uniformity in the rotation angles of the micro-mirrors can increase the dispersion of the reflected light and reduce the imaging/ranging resolution.

The control precision limitation can come from various sources, such as, for example, variations in the fabrication process and non-idealities in the actuator and/or in the transmission of the control signal. Specifically, the control signal can be determined based on a required torque for a target rotation angle, and the required torque may be determined based on a predetermined spring stiffness of the connection structures. The actual spring stiffness may depend on the dimension of the connection structures, which may vary due to variations in the fabrication process. As a result, the predetermined spring stiffness may not match the actual spring stiffness. As another example, the actuator may not create the target torque in response to the control signal due to various non-idealities. For example, due to electrical resistance of the transmission paths of the control signal, the amplitude of the control signal can be reduced when it arrives at the actuator. In all these cases, the actual rotation angle of the micro-mirror may not match the target rotation angle, which leads to degradation in the control precision of the micro-mirror.

### Conceptual Overview of Certain Embodiments

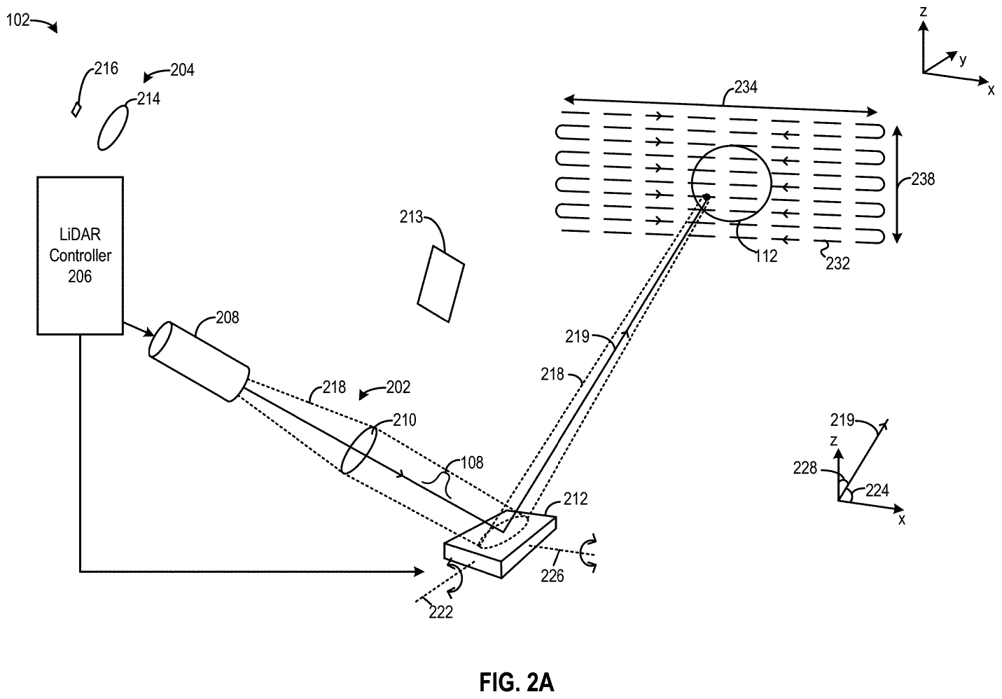

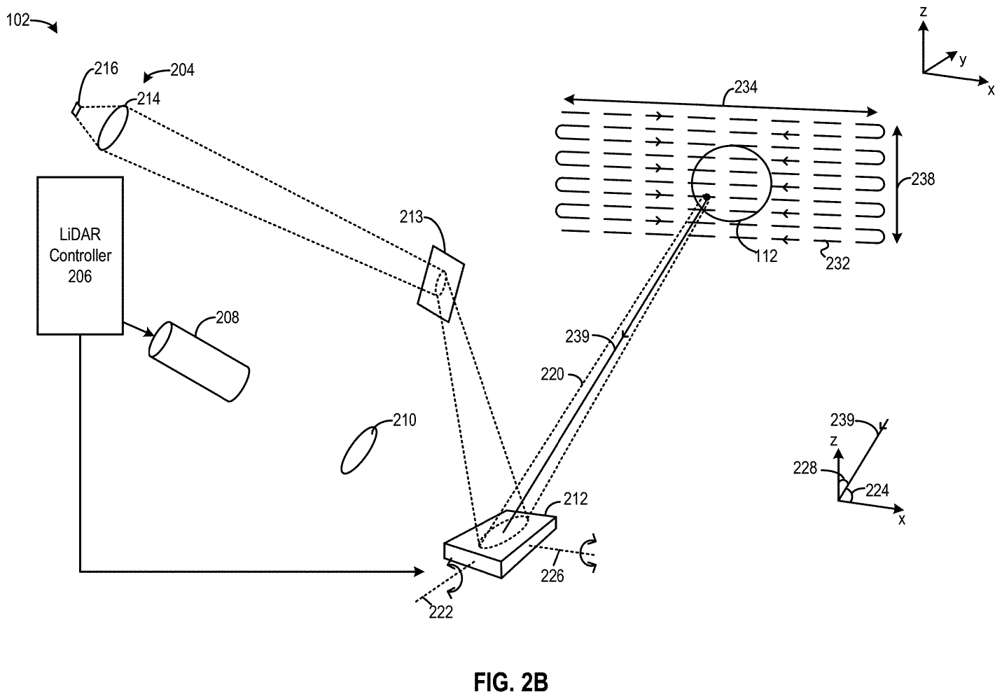

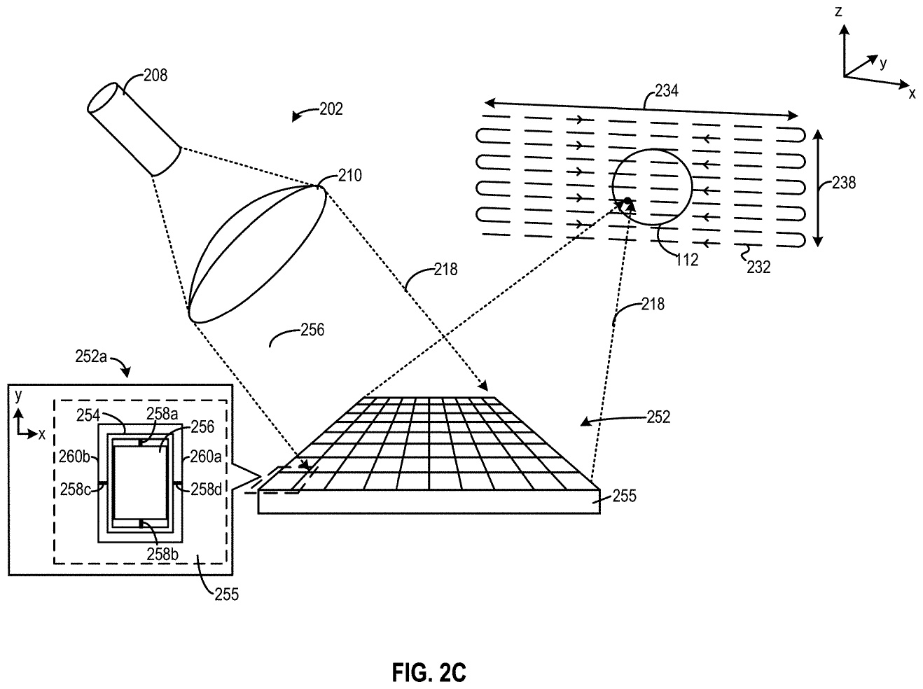

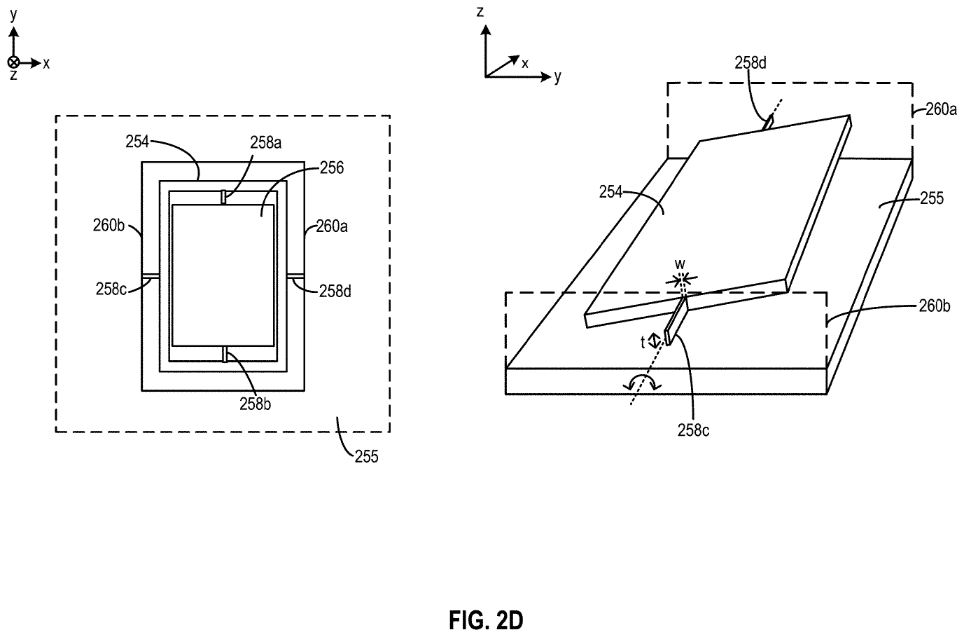

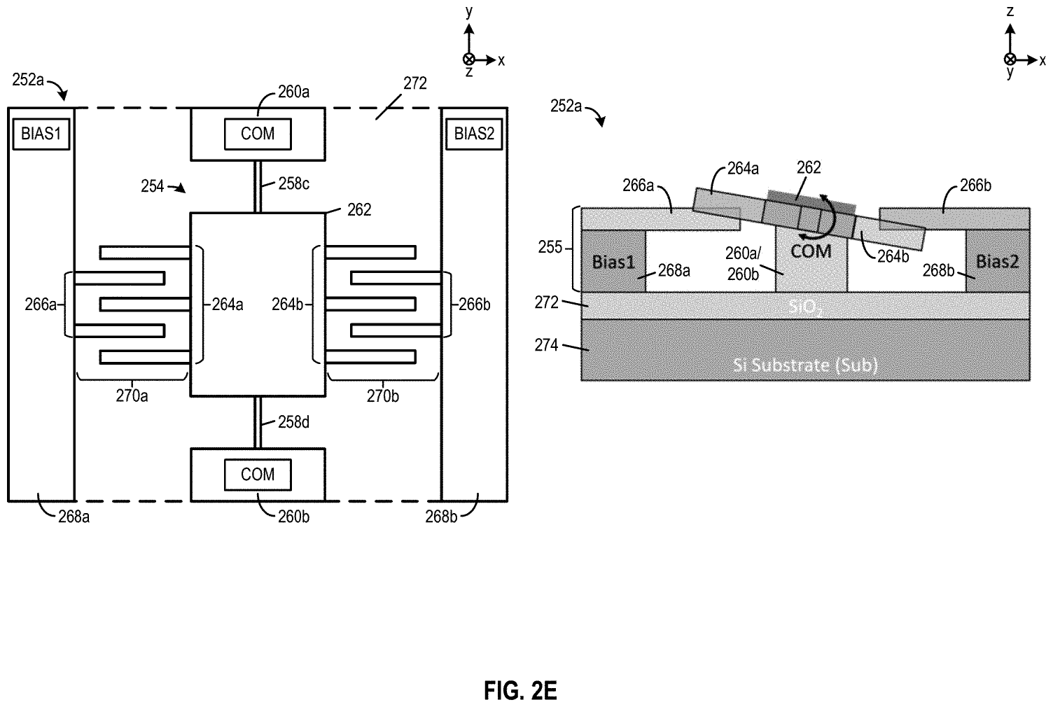

Examples of the present disclosure relate to a light steering system that can address the problems described above. As shown in FIG. 2A and FIG. 2B, the light steering system can be used as part of a transmitter to control a direction of projection of output light. The light steering system can also be used as part of a receiver to select a direction of input light to be detected by the receiver. The light steering system can also be used in a coaxial configuration such that the light steering system can project output light to a location and detects light reflected from that location. Various embodiments of the light steering can include a plurality of mirrors to perform light steering, such as those shown and described below with respect to FIG. 2C.

In some examples, a light steering system includes a semiconductor integrated circuit. The semiconductor integrated circuit includes an MEMS, an oxide layer, and a semiconductor substrate fabricated from a silicon-on-insulator (SOI) wafer. The MEMS can be formed on the semiconductor substrate, with the oxide layer sandwiched between the MEMS and the semiconductor substrate.

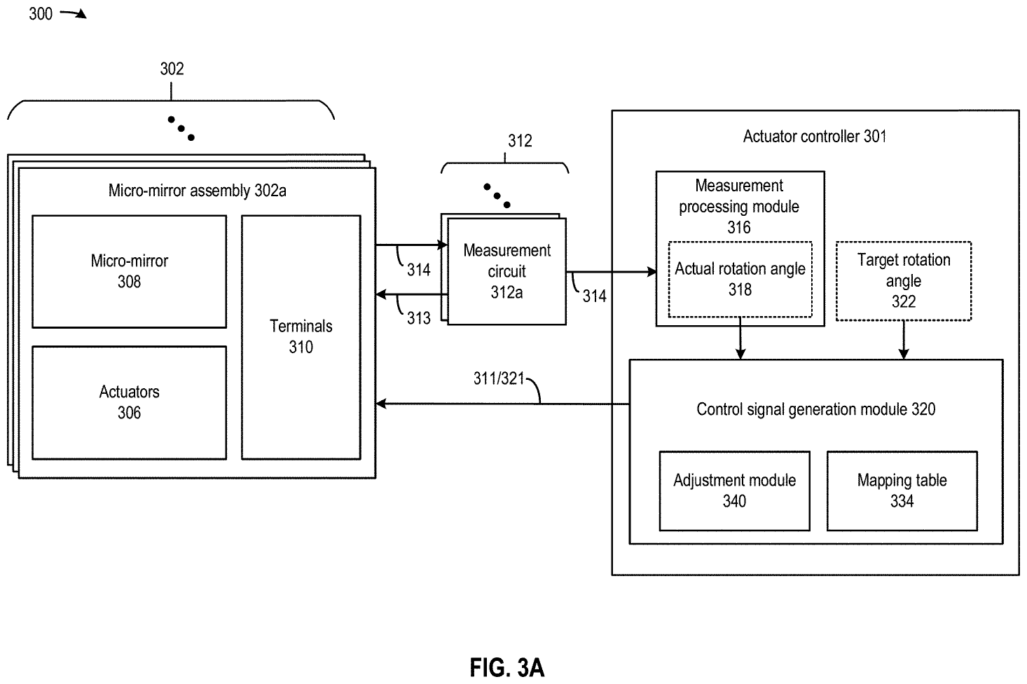

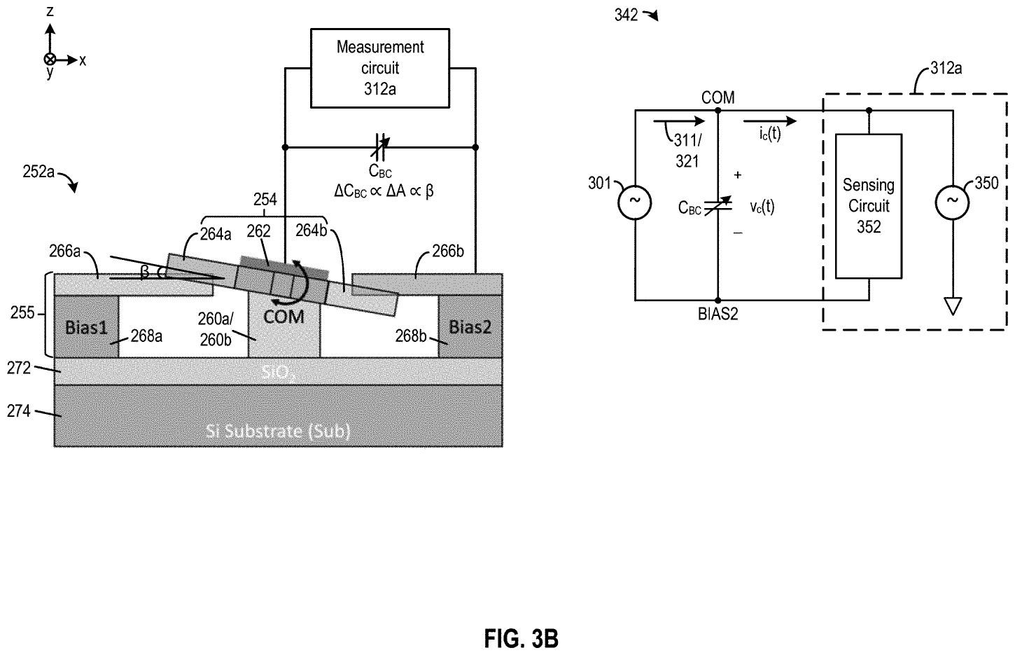

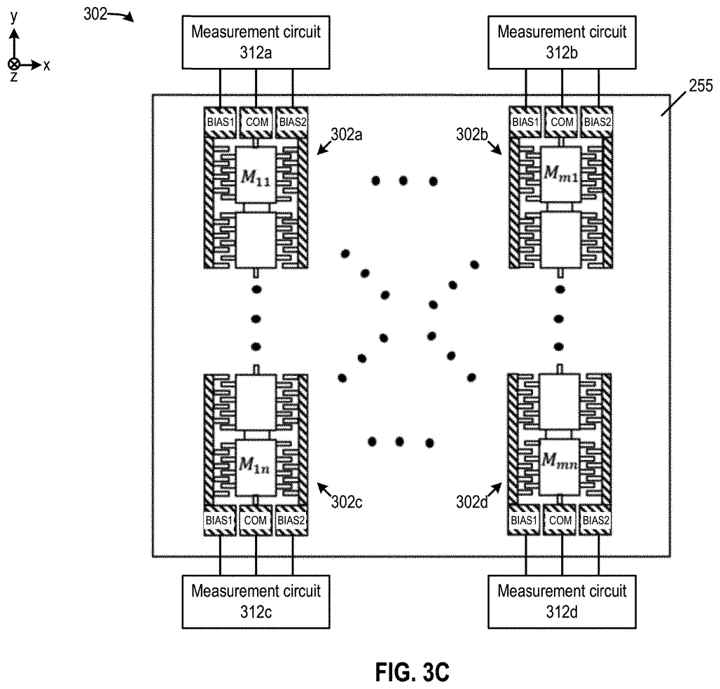

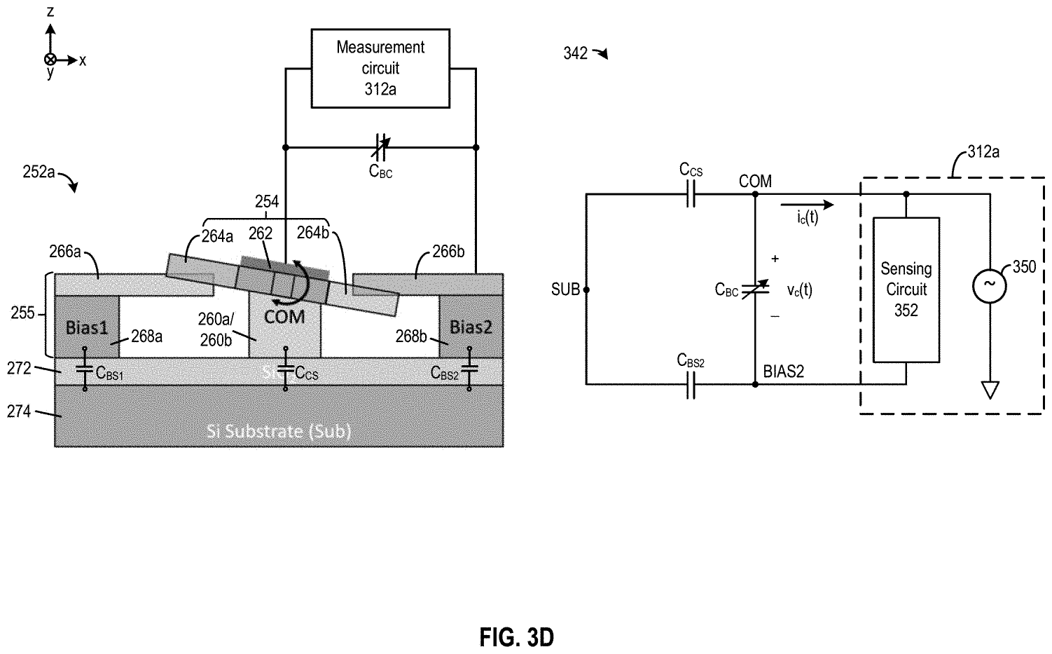

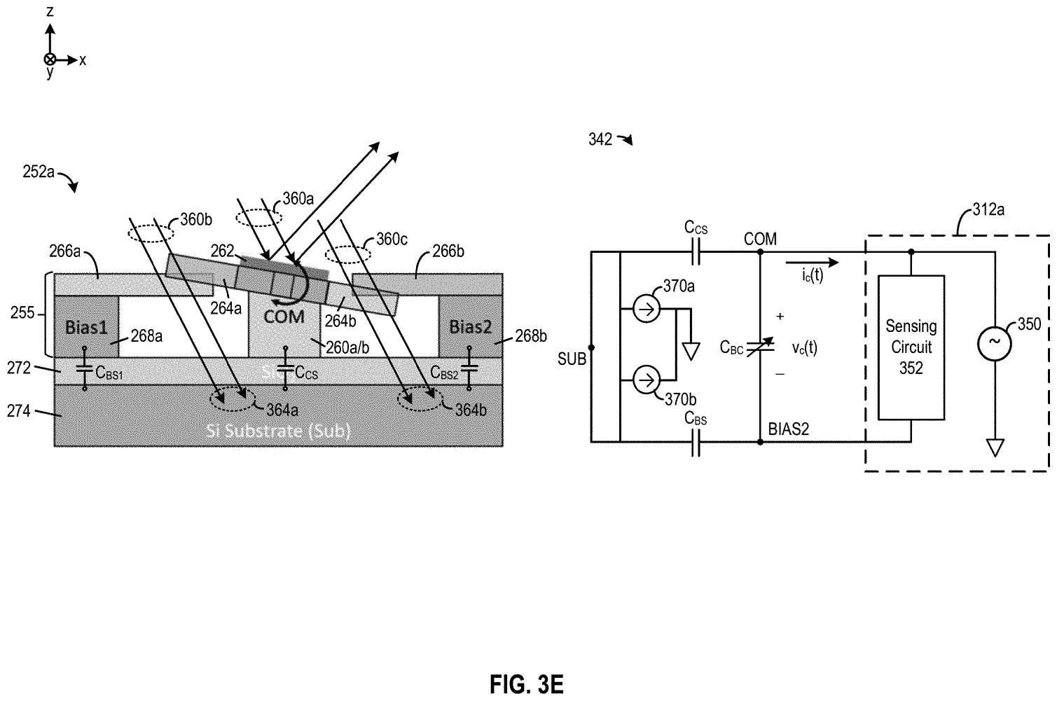

Examples of the semiconductor integrated circuit is shown in FIG. 3A-FIG. 3E. The MEMS includes an array of micro-mirror assemblies. Each micro-mirror assembly includes a micro-mirror. Referring to FIG. 3B, the micro-mirror has a reflective surface to reflect incident light and a set of rotor electrodes on the periphery of the reflective surface. The micro-mirror is connected to mirror anchors on the semiconductor substrate via a pair of connection structures, which can be in the form of torsion bars and/or, springs. The connection structures can form a pair of pivot points around which the micro-mirror rotates. Each micro-mirror assembly further includes a set of stator electrodes connected to electrode anchors on the semiconductor substrate. The set of rotor electrodes and stator electrodes can form an actuator, in which each set of electrodes can receive a control signal and generate a force (e.g., a magnetic force, an electrostatic force) against each other. The force can create a torque to rotate the micro-mirror around a first axis. The micro-mirror assemblies further includes contact terminals that are electrically connected to the electrodes to receive the control signals. In some examples, referring to FIG. 2D, the micro-mirror includes a gimbal/frame that surrounds the reflective surface, and the connection structures can connect between the gimbal and the substrate. The micro-mirror can have additional sets of stator and rotor electrodes to rotate the reflective surface with respect to the gimbal around a second axis.

Referring back to FIG. 3A, the semiconductor integrated circuit further includes a controller. The controller is configured to, for each micro-mirror assembly, determine a control signal based on a target rotation angle of the micro-mirror and transmit the first signal to the actuator of each micro-mirror assembly. The control signal can cause the stator electrodes and the rotor electrodes of each micro-assembly to generate a force (e.g., a magnetic force, an electrostatic force) against each other based on the target rotation angle. The force can create a torque to rotate the micro-mirror by a rotation angle which can be equal to or different from the target rotation angle.

To improve the control precision of the rotation angle of the array of micro-mirror assemblies, the semiconductor integrated circuit can implement a feedback loop to measure the actual rotation angle of at least some of the micro-mirror assemblies in response to the control signal. The controller can then adjust the control signal based on a difference between the actual rotation angle and the target rotation angle. Referring to FIG. 3A, the semiconductor integrated circuit further includes a measurement circuit to measure the actual rotation angle of at least some of the micro-mirror assemblies. The measurement can be based on measuring the capacitances of various components of the micro-mirror assembly. For example, referring to FIG. 3B, the measurement circuit can measure a capacitance between the rotor electrodes of the micro-mirror and the stator electrodes (hereinafter, electrode capacitance) which can reflect an overlapping area between the rotor and stator electrodes, which can reflect the rotation angle of the micro-mirror. The measurement circuit can measure the electrode capacitance based on, for example, applying an AC voltage as a measurement signal at a much higher frequency than that of the control signal and the rotation of the micro-mirror across the stator and rotor electrodes to charge/discharge the electrode capacitance. The AC voltage can charge and then discharge the electrode capacitance in each AC cycle. An instantaneous voltage across the stator and rotor electrodes, as well as the instantaneous current that flows through the stator (or rotor) electrodes during the charging and discharging in each AC cycle, can be measured. The voltage and current can be used to determine the reactance, which can reflect the electrode capacitance.

In some examples, the measurement circuit can measure the electrode capacitance at a number of representative micro-mirror assemblies, and use the measurement results to represent the electrode capacitances of the rest of the micro-mirror assemblies. For example, referring to FIG. 3C, measurement circuits can measure the electrode capacitance of four corner micro-mirror assemblies. An average of the electrode capacitances can be obtained, and the averaged electrode capacitance can be used to determine the actual rotation angles of the rest of the micro-mirror assemblies. In some examples, the measurement circuit can also measure the electrode capacitance of each micro-mirror assembly individually, which allows the controller to determine the actual rotation angle of each micro-mirror assembly individually, and adjust the control signal for each micro-mirror assembly individually.

The accuracy of the electrode capacitance measurement, however, can be hindered by various parasitic capacitances in the semiconductor substrate. Referring to FIG. 3D, a micro-mirror assembly can have parasitic capacitances formed between the mirror anchors and the substrate, and between the electrode anchors and the substrate, with the oxide layer acting as a dielectric. Referring to FIG. 3E, some of the incident light that are to be reflected by the micro-mirror can enter the semiconductor substrate via gaps between the stator and rotor electrodes. Photocurrent can be generated in the semiconductor substrate as a result, and the photocurrent can charge/discharge the parasitic capacitances. The charging/discharging of the parasitic capacitance can introduce an error component to the reactance measurement, as the error component is not caused by the AC voltage and does not reflect the rotation angle of the micro-mirror. As a result, the correspondence between the measured capacitance and the actual rotation angle is reduced, which in turn can reduce the control precision of the micro-mirror.

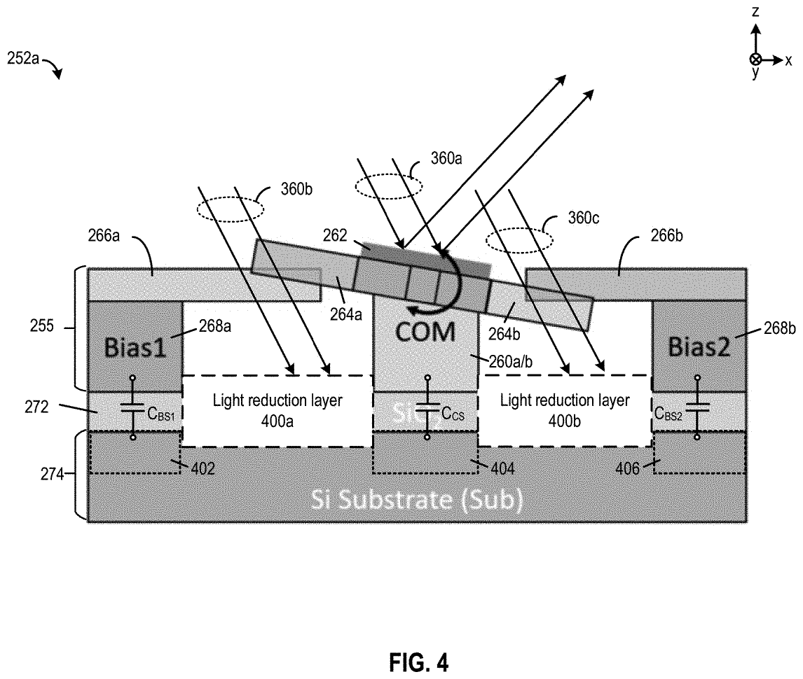

FIG. 4-FIG. 16B illustrate example structures to reduce the effect of photocurrent on the electrode capacitance measurement, as well as example fabrication processes for the example structures. Referring to FIG. 4, a micro-mirror assembly can include a light reduction layer positioned below the stator and rotor electrodes. In some examples, the light reduction layer can reduce the amount of incident light that enters the semiconductor substrate, and thereby reduce the photocurrent generated by the semiconductor substrate and the resulting photo charge accumulated at the parasitic capacitances. In some examples, the light reduction layer can also be formed within the semiconductor substrate. The light reduction layer can prevent the incident light from entering parts of the semiconductor substrate that form the parasitic capacitances, and thereby reducing the photocurrent that flow into and charge the parasitic capacitances.

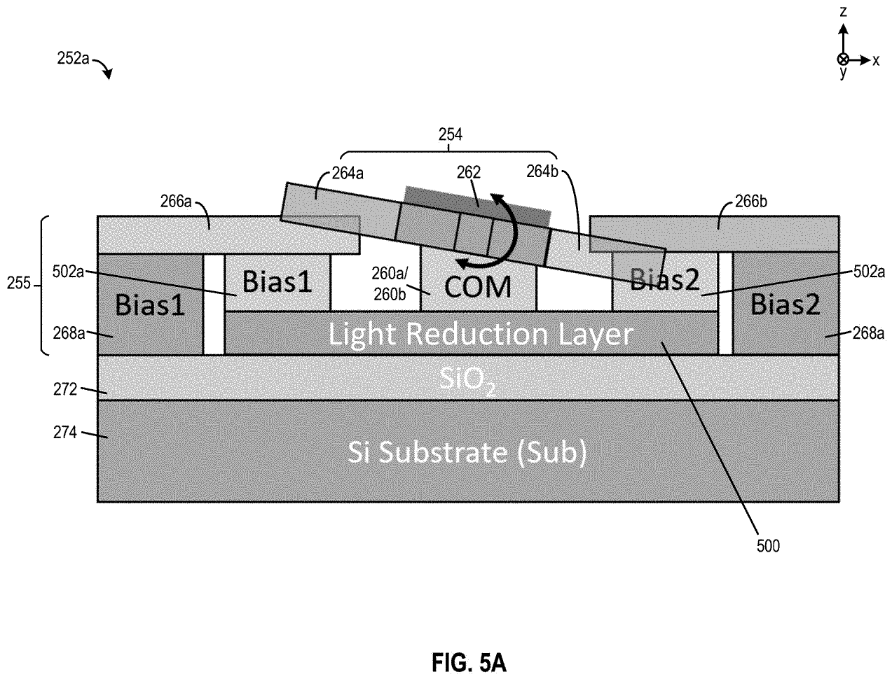

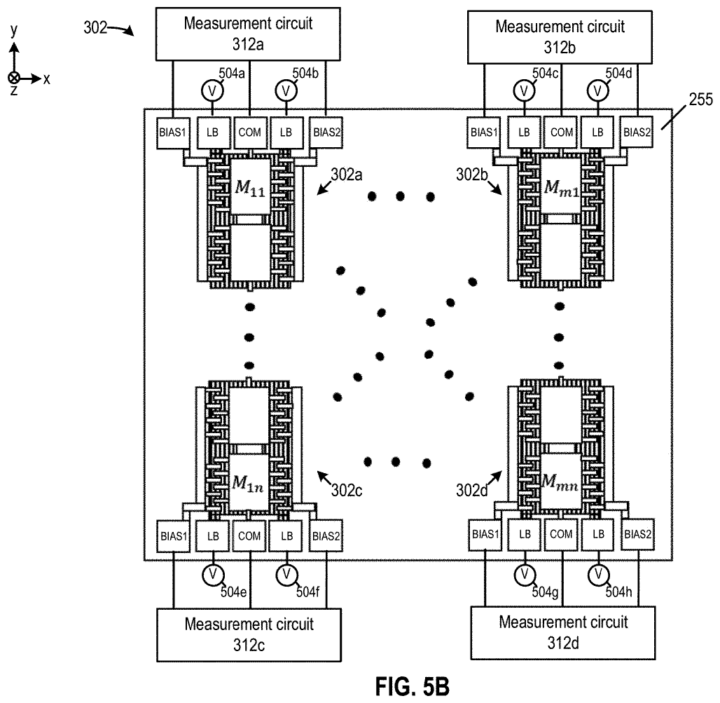

The light block layer can be in different forms and fabricated with different methods. For example, referring to FIG. 5A and FIG. 5B, the light reduction layer can be formed as a semiconductor layer between the mirror anchors and the oxide layer. The light reduction layer can be connected to a current sink (e.g., a voltage source) via terminals formed on the semiconductor substrate that are separate from the terminals for transmitting the control signals and measurement signals. The light reduction layer can absorb the incident light and convert the photons into photocurrent, which can be steered into the current sink and away from the parasitic capacitances.

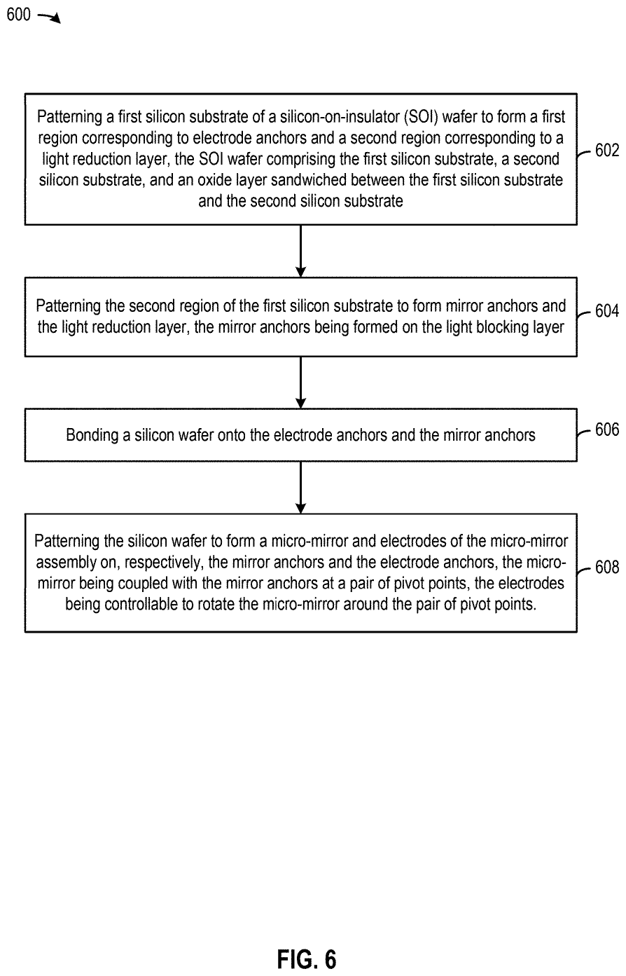

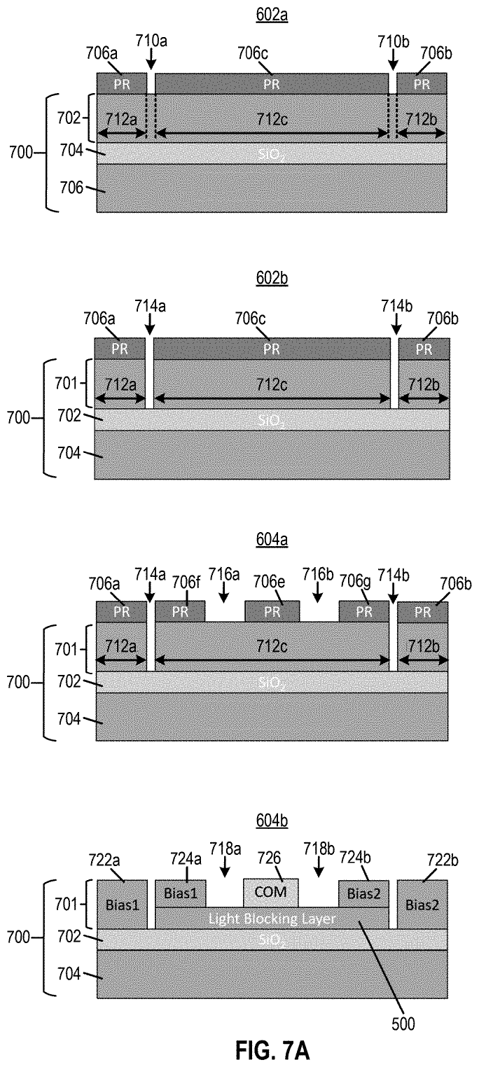

Referring to FIG. 6, FIG. 7A, and FIG. 7B, a micro-mirror assembly having the light reduction layer of FIG. 5A can be fabricated from a SOI wafer having a first semiconductor substrate, an oxide layer, and a second semiconductor substrate. A first deep reactive-ion process (DRIP), which stops at the oxide layer, can be performed to pattern the first semiconductor substrate into a first region corresponding to the electrode anchors and a second region. A second DRIP can then be performed to pattern the second region to form the light reduction layer, as well as the mirror anchors and, in some examples, another set of electrode anchors on the light reduction layer. The second DRIP can stop at a certain distance above the oxide, to create a cavity that can accommodate the rotation of the micro-mirror. A semiconductor wafer (e.g., a silicon wafer) can be positioned onto and bonded to the mirror anchors and the electrode anchors. A third DRIP can be performed to pattern the semiconductor wafer into the stator electrodes, the micro-mirror having the rotor electrodes, the connection structures between the micro-mirror and the mirror anchors, etc.

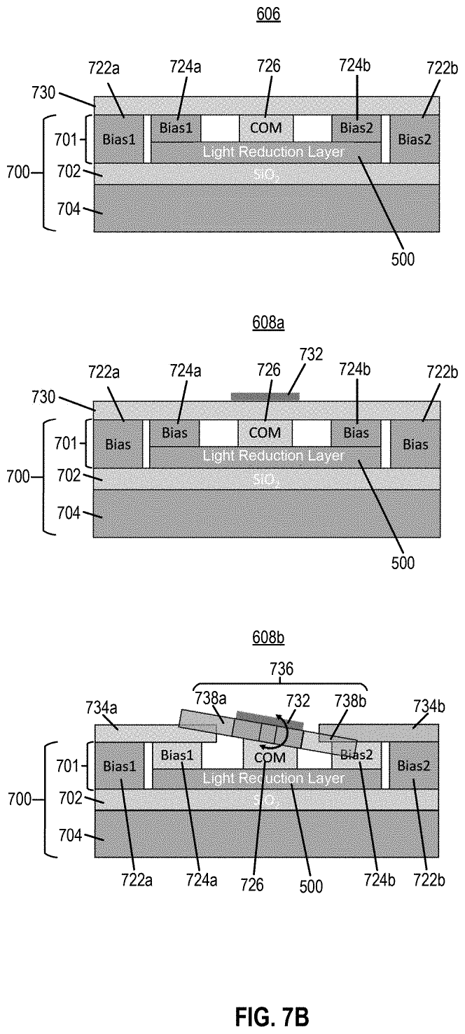

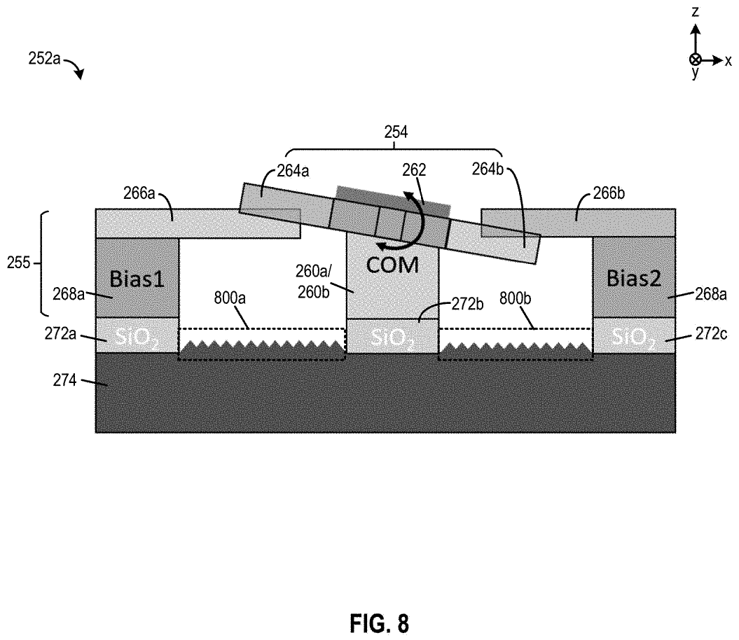

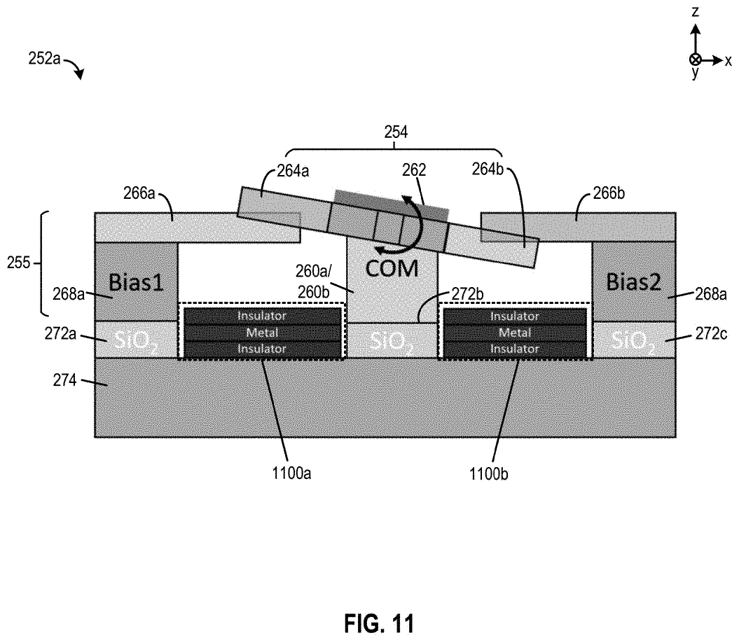

In some examples, referring to FIG. 8 and FIG. 11, the light reduction layer can be formed on a surface of the semiconductor substrate to prevent the incident light from entering the semiconductor substrate. In some examples, as shown in FIG. 8, the light reduction layer can be formed as a roughened surface of the semiconductor substrate. The roughened surface can absorb the incident light via a recombination operation and convert the incident light into thermal energy. Moreover, as shown in FIG. 11, a stacked light reduction layer can include a reflective layer sandwiched between two insulator layers and formed on the surface of the semiconductor layer. The light reduction layer can reflect incident light away from the semiconductor substrate and prevent the light from entering the semiconductor substrate.

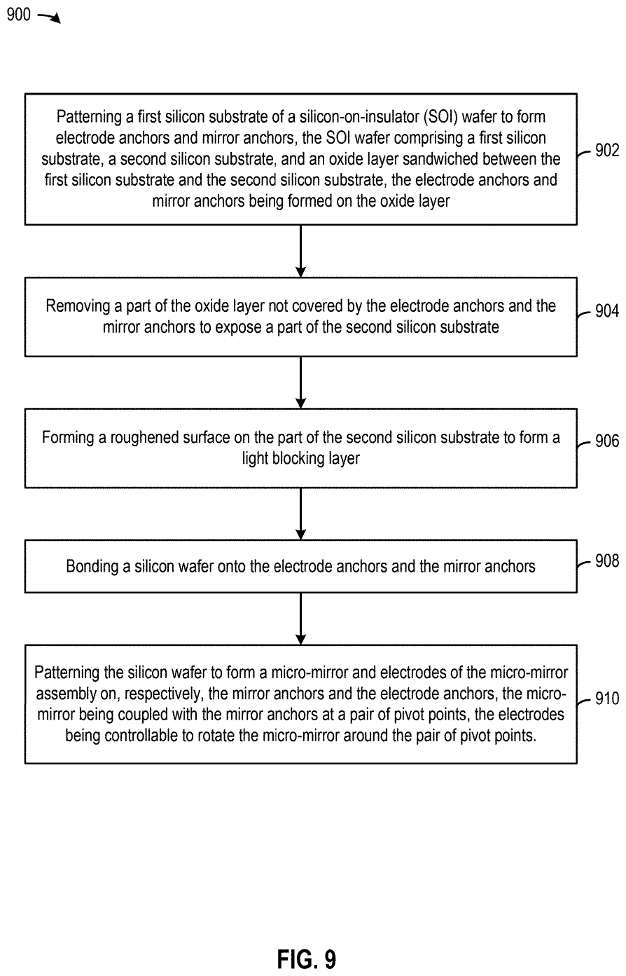

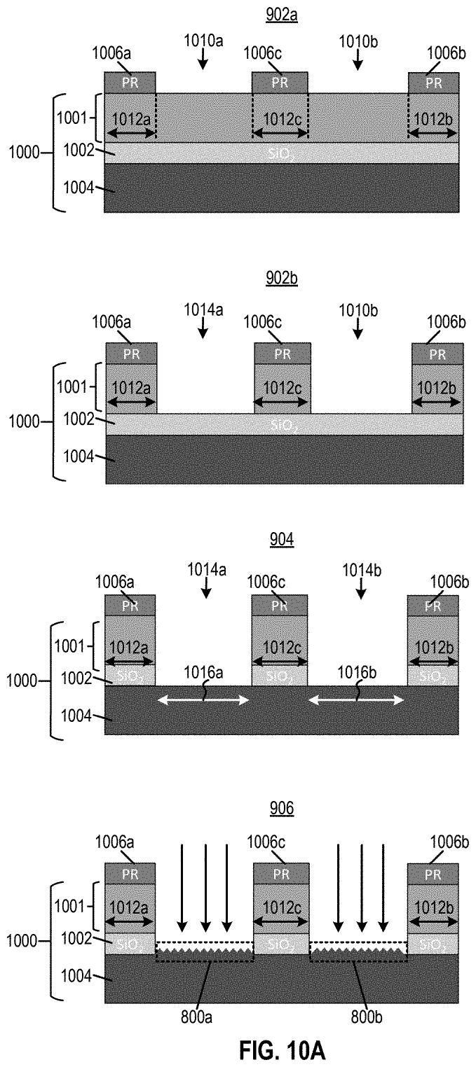

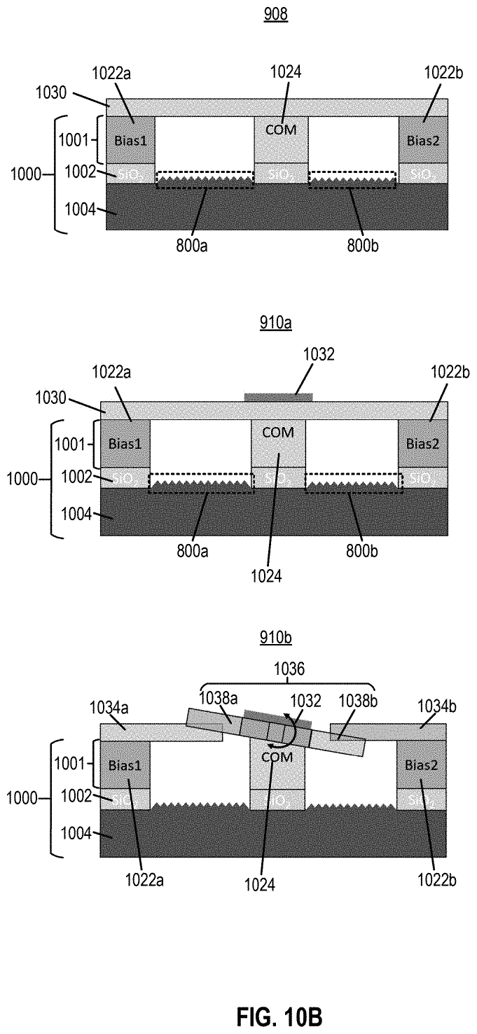

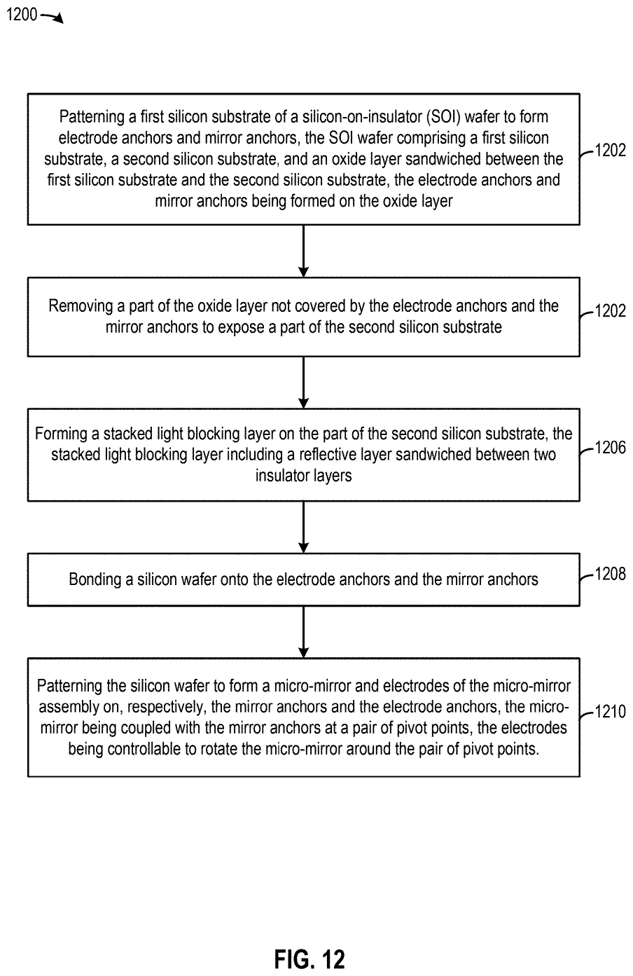

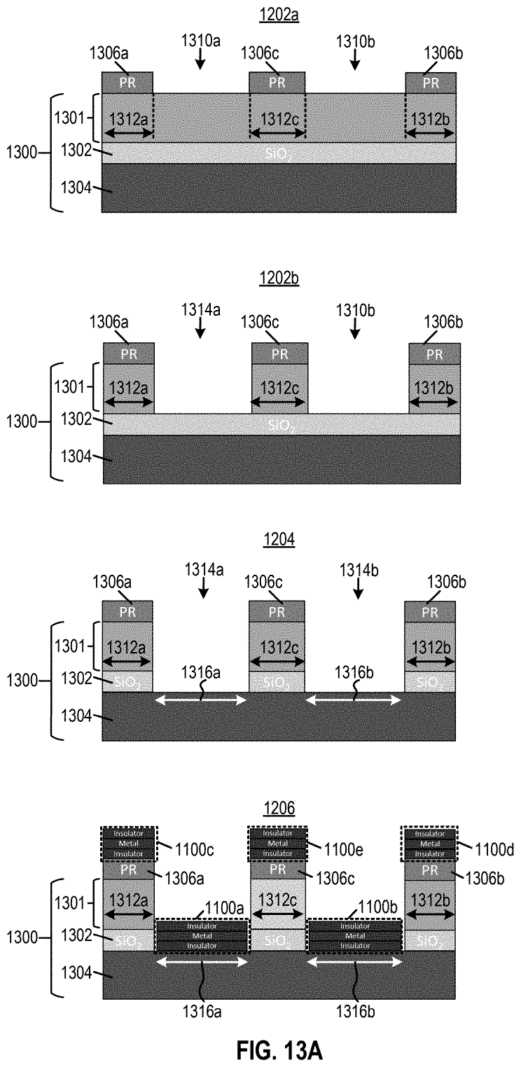

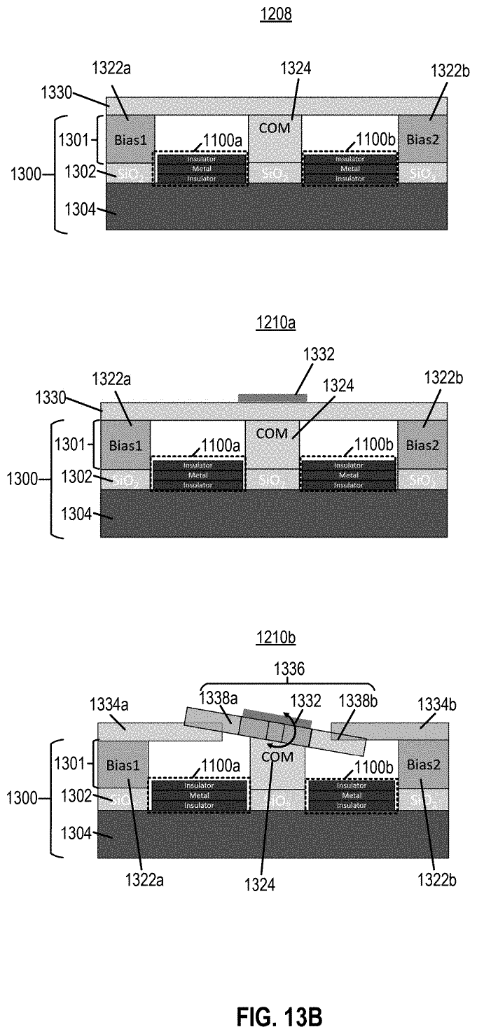

Referring to FIG. 9 and FIG. 12, a micro-mirror assembly having the light reduction layer of FIG. 8 and FIG. 11 can be fabricated from a SOI wafer having a first semiconductor substrate, an oxide layer, and a second semiconductor substrate. Referring to FIG. 10A and FIG. 10B, a first DRIP process, which stops at the oxide layer, can be performed to pattern the first semiconductor substrate into first regions and second regions. The first regions can correspond to the electrode anchors and the mirror anchors, while the second regions can expose the oxide layer. An oxide etching operation can then be performed on the second regions to remove the exposed oxide layer and to expose the second semiconductor substrate under the second regions. A dry etch process can be performed on the second region to create the roughened surface of the second semiconductor substrate to form the light reduction layer of FIG. 8. Moreover, referring to FIG. 13A and FIG. 13B, a film deposition operation can be performed to deposit multiple layers of films on the exposed second semiconductor substrate within the second regions to form the stacked light reduction layer of FIG. 11 on the second semiconductor substrate. The film deposition operation can include a physical vapor deposition operation, which can include, for example, sputtering, pulsed laser deposition, thermal and e-beam evaporation. A semiconductor wafer can then be positioned onto and bonded to the mirror anchors and the electrode anchors, followed by a second DRIP to pattern the semiconductor wafer into the stator electrodes, the micro-mirror having the rotor electrodes, the connection structures between the micro-mirror and the mirror anchors, etc.

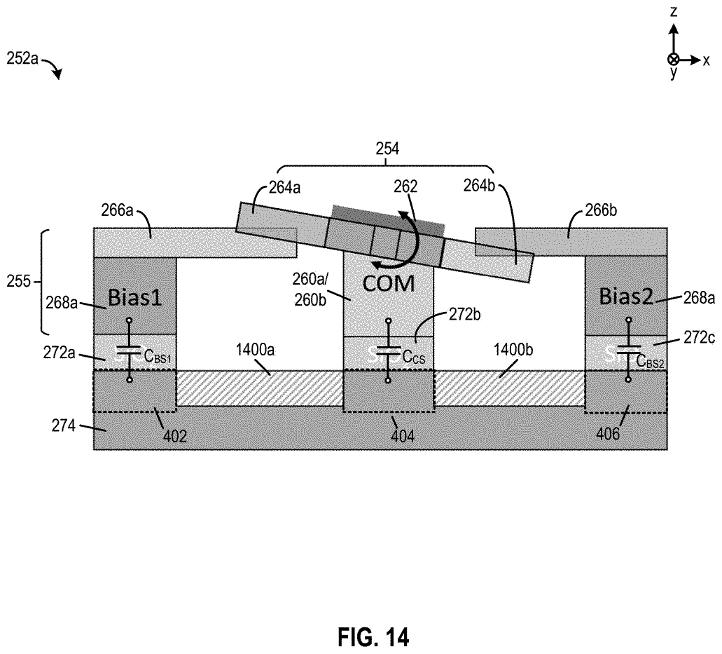

In some examples, referring to FIG. 14, the light reduction layer can be formed below a surface of the semiconductor substrate. The light reduction layer can absorb the incident light that enters the semiconductor substrate and reduce the amount of light that enter parts of the semiconductor substrate below the mirror anchors and the electrode anchor. Such arrangements can reduce the generation of photocurrent and accumulation of photo charge at the parasitic capacitances. In addition, the light reduction layer can have a higher concentration of charge carriers than parts of the semiconductor substrate that form the parasitic capacitances. The higher concentration of charge carriers can be due to, for example, the light reduction layer being more heavily doped than other parts of the semiconductor substrate. Such arrangements allow the photo charge generated by the light reduction layer to quickly recombine with the charge carriers and prevent the photo charge from flowing into the parasitic capacitances.

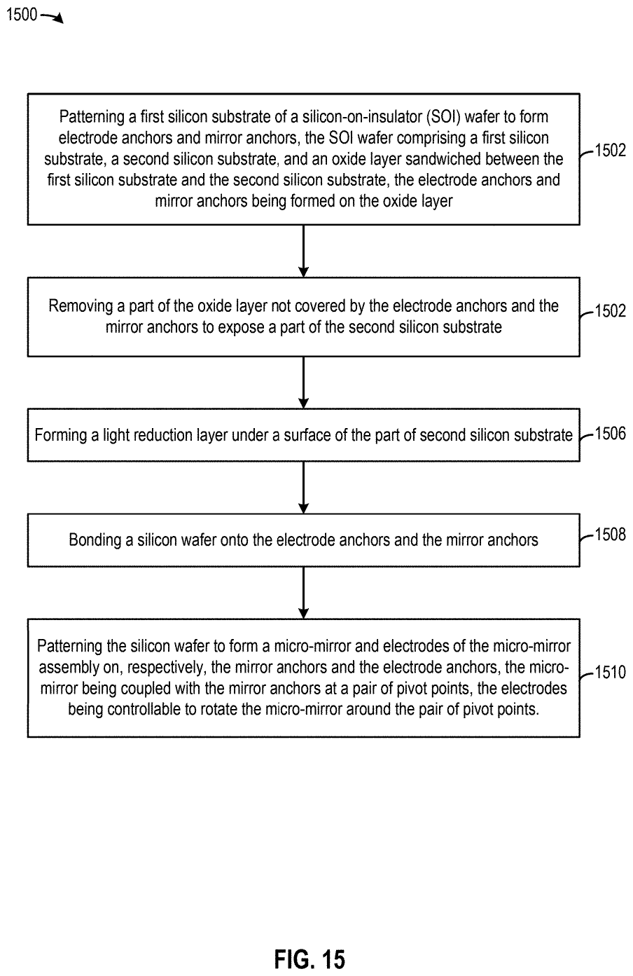

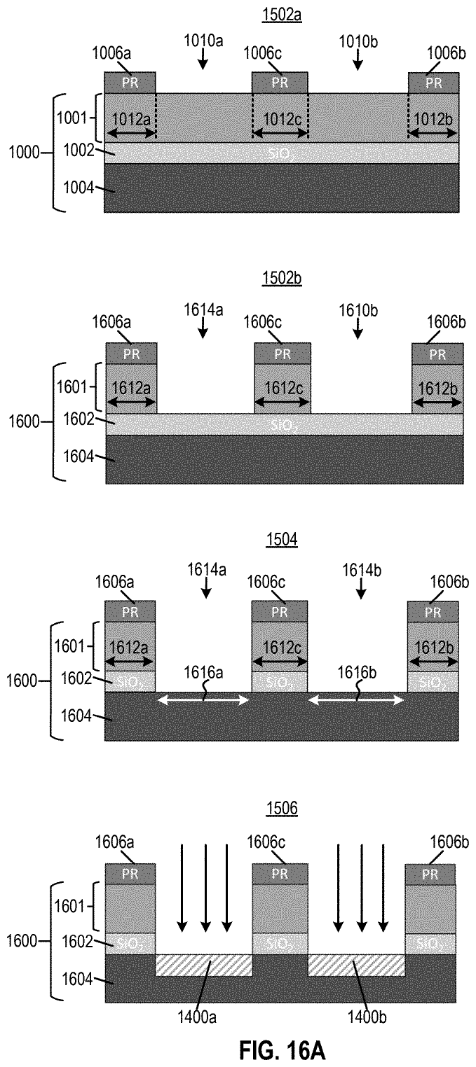

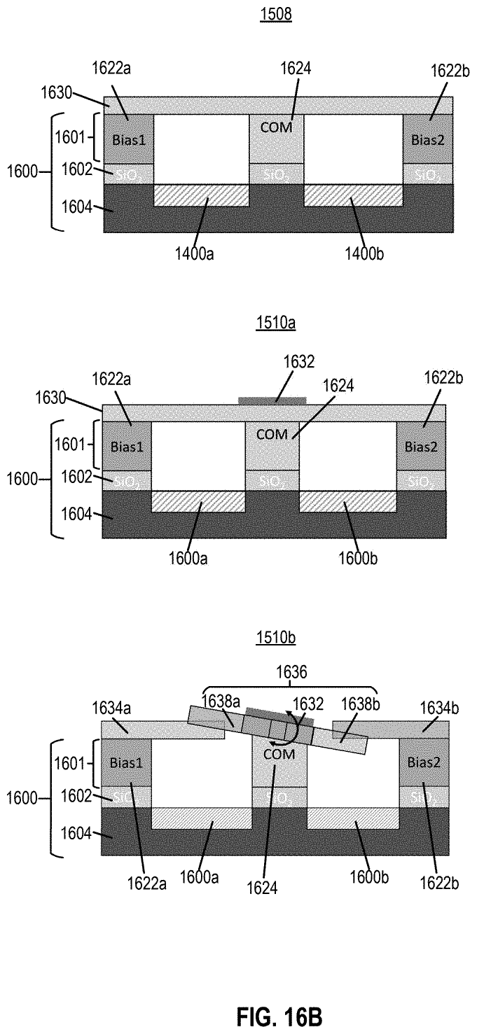

Referring to FIG. 15, FIG. 16A, and FIG. 16B, a micro-mirror assembly having the light reduction layer of FIG. 14 can be fabricated from a SOI wafer having a first semiconductor substrate, an oxide layer, and a second semiconductor substrate. A first DRIP process, which stops at the oxide layer, can be performed to pattern the first semiconductor substrate into first regions and second regions. The first regions can correspond to the electrode anchors and the mirror anchors, while the second regions can expose the oxide layer. An oxide etching operation can then be performed on the second regions to remove the exposed oxide layer and to expose the second semiconductor substrate under the second regions. An ion implantation operation can be performed on the second region to create the light reduction layer below a surface of the second semiconductor substrate within the second region. A semiconductor wafer can then be positioned onto and bonded to the mirror anchors and the electrode anchors, followed by a second DRIP to pattern the semiconductor wafer into the stator electrodes, the micro-mirror having the rotor electrodes, the connection structures between the micro-mirror and the mirror anchors, etc.

With the disclosed techniques, a light reduction layer can be provided to reduce or eliminate the generation of photocurrent by the semiconductor substrate due to incident light that go through gaps between the stator and rotor electrodes. The error component in the reactance measurement due to the charging/discharging of the parasitic capacitance by the photocurrent can be reduced. The correspondence between the measured capacitance and the actual rotation angle can improve. As a result, the control precision of the micro-mirror, based on the measured capacitance, can also be improved. All of these can improve the robustness and performance of a light steering system.

### Typical System Environment for Certain Examples

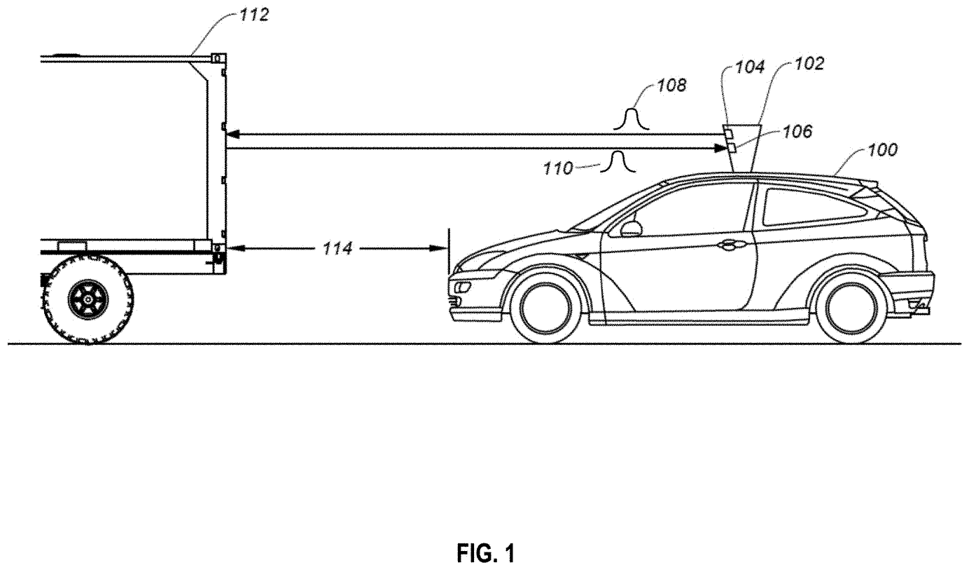

FIG. 1 illustrates an autonomous vehicle 100 in which the disclosed techniques can be implemented. Autonomous vehicle 100 includes a LiDAR module 102. LiDAR module 102 allows autonomous vehicle 100 to perform object detection and ranging in a surrounding environment. Based on the result of object detection and ranging, autonomous vehicle 100 can maneuver to avoid a collision with the object. LiDAR module 102 can include a light steering transmitter 104 and a receiver 106. Light steering transmitter 104 can project one or more light signals 108 at various directions at different times in any suitable scanning pattern, while receiver 106 can monitor for a light signal 110, which is generated by the reflection of light signal 108 by an object. Light signals 108 and 110 may include, for example, a light pulse, a frequency modulated continuous wave (FMCW) signal, or an amplitude modulated continuous wave (AMCW) signal. LiDAR module 102 can detect the object based on the reception of light pulse 110 and can perform a ranging determination (e.g., a distance of the object) based on a time difference between light signals 108 and 110. For example, as shown in FIG. 1, LiDAR module 102 can transmit light signal 108 at a direction directly in front of autonomous vehicle 100 at time T1 and receive light signal 110 reflected by an object 112 (e.g., another vehicle) at time T2. Based on the reception of light signal 110, LiDAR module 102 can determine that object 112 is directly in front of autonomous vehicle 100. Moreover, based on the time difference between T1 and T2, LiDAR module 102 can also determine a distance 114 between autonomous vehicle 100 and object 112. Autonomous vehicle 100 can adjust its speed (e.g., by slowing or stopping) to avoid collision with object 112 based on the detection and ranging of object 112 by LiDAR module 102.

FIGS. 2A-2E illustrate examples of internal components of a LiDAR module 102. LiDAR module 102 includes a transmitter 202, a receiver 204, and a LiDAR controller 206, which controls the operations of transmitter 202 and receiver 204. Transmitter 202 includes a light source 208 and a collimator lens 210, whereas receiver 204 includes a lens 214 and a photodetector 216. LiDAR module 102 further includes a mirror assembly 212 and a beam splitter 213. In LiDAR module 102, transmitter 202 and receiver 204 can be configured as a coaxial system to share mirror assembly 212 to perform light steering operation, with beam splitter 213 configured to reflect incident light reflected by mirror assembly 212 to receiver 204.

FIG. 2A illustrates a light projection operation. To project light, LiDAR controller 206 can control light source 208 (e.g., a pulsed laser diode, a source of FMCW signal, AMCW signal) to transmit light signal 108 as part of light beam 218. Light beam 218 can disperse upon leaving light source 208 and can be converted into collimated light beam 218 by collimator lens 210. Collimated light beam 218 can be incident upon a mirror assembly 212, which can reflect collimated light beam 218 to steer it along an output projection path 219 towards object 112. Mirror assembly 212 can include one or more rotatable mirrors. FIG. 2A illustrates mirror assembly 212 as having one mirror, but as to be described below, a micro-mirror array comprising multiple micro-mirror assemblies can be used to provide the steering capability of mirror assembly 212. Mirror assembly 212 further includes one or more actuators (not shown in FIG. 2A) to rotate the rotatable mirrors. The actuators can rotate the rotatable mirrors around a first axis 222 and can rotate the rotatable mirrors along a second axis 226. The rotation around first axis 222 can change a first angle 224 of output projection path 219, with respect to a first dimension (e.g., the x-axis), whereas the rotation around second axis 226 can change a second angle 228 of output projection path 219, with respect to a second dimension (e.g., the z-axis). LiDAR controller 206 can control the actuators to produce different combinations of angles of rotation around first axis 222 and second axis 226 such that the movement of output projection path 219 can follow a scanning pattern 232. A range 234 of movement of output projection path 219 along the x-axis, as well as a range 238 of movement of output projection path 219 along the z-axis, can define an FOV. An object within the FOV, such as object 112, can receive and reflect collimated light beam 218 to form reflected light signal, which can be received by receiver 204.

FIG. 2B illustrates a light detection operation. LiDAR controller 206 can select an incident light direction 239 for detection of incident light by receiver 204. The selection can be based on setting the angles of rotation of the rotatable mirrors of mirror assembly 212, such that only light beam 220 propagating along light direction 239 gets reflected to beam splitter 213, which can then divert light beam 220 to photodetector 216 via collimator lens 214. With such arrangements, receiver 204 can selectively receive signals that are relevant for the ranging/imaging of object 112, such as light signal 110 generated by the reflection of collimated light beam 218 by object 112, and not to receive other signals. As a result, the effect of environment disturbance on the ranging/imaging of the object can be reduced and the system performance can be improved.

FIG. 2C illustrates an example of a micro-mirror array 250 that can be part of light steering transmitter 202 and can provide the steering capability of mirror assembly 212. Micro-mirror array 250 can include an array of micro-mirror assemblies 252, including micro-mirror assembly 252a. FIG. 2D illustrates an example of micro-mirror assembly 252a. The array of micro-mirror assemblies 252 can include an MEMS device layer implemented on a semiconductor substrate 255. Each of micro-mirror assemblies 252 may include a frame 254 and a micro-mirror 256 forming a gimbal structure. Specifically, connection structures 258a and 258b connect micro-mirror 256 to frame 254, whereas connection structures 258c and 258d connect frame 254 (and micro-mirror 256) to mirror anchors 260a and 260b of semiconductor substrate 255. A pair of connection structures can define a pivot/axis of rotation for micro-mirror 256. For example, connection structures 258a and 258b can define a pivot/axis of rotation of micro-mirror 256 about the y-axis within frame 254, whereas connection structures 258c and 258d can define a pivot/axis of rotation of frame 254 and micro-mirror 256 about the x-axis with respect to semiconductor substrate 255.

Each of micro-mirror assemblies 252 can receive and reflect part of light beam 218. The micro-mirror 256 of each of micro-mirror assemblies 252 can be rotated by an actuator of the micro-mirror assembly (not shown in FIG. 2C) at a first angle about the y-axis (around connection structures 258a and 258b) and at a second angle about the x-axis (around connection structures 258c and 258d) to set the direction of output projection path for light beam 218 and to define the FOV, as in FIG. 2A, or to select the direction of input light to be detected by receiver 204, as in FIG. 2B.

To accommodate the rotation motion of mirror 256, connection structures 258a, 258b, 258c, and 258d are configured to be elastic and deformable. The connection structure can be in the form of, for example, a torsion bar or a spring and can have a certain spring stiffness. The spring stiffness of the connection structure can define a torque required to rotate mirror 256 by a certain rotation angle, as follows:

τ=−Kθ (Equation 1)

In Equation 1, τ represents torque and K represents a spring constant that measures the spring stiffness of the connection structure, whereas θ represents a target rotation angle. The spring constant can depend on various factors, such as the material of the connection structure or the cross-sectional area of the connection structure. For example, the spring constant can be defined according to the following equation:

$$K = \frac{{k}_{2} \times G \times {w}^{3} \times t}{L} \qquad ( Equation 2 )$$

In Equation 2, L is the length of the connection structure, G is the shear modulus of material that forms the connection structure, and k₂ is a factor that depends on the ratio between thickness (t) and width (w) given as t/w. The larger the ratio t/w, the more k₂ is like a constant.

The table below provides illustrative examples of k₂ for different ratios of t/w:

| Ratio of t/w | k₂ |
|---|---|
| 1 | 0.141 |
| 2 | 0.229 |
| 3 | 0.263 |
| 6 | 0.298 |
| ∞ | 0.333 |

In a case where w is one-third oft or less, k₂ becomes almost like a constant, and spring constant K can be directly proportional to thickness.

Various types of actuators can be included in micro-mirror assemblies 252 to provide the torque, such as an electrostatic actuator, an electromagnetic actuator, or a piezoelectric actuator. FIG. 2E illustrates an example of micro-mirror assembly 252a which includes an actuator. As shown in FIG. 2E, micro-mirror assembly 252a includes a pair of mirror anchors 260a and 260b connected to micro-mirror 256 via, respectively, connection structures 258a and 258d. Micro-mirror 256 further includes a reflective surface 262 and a set of rotor electrodes 264a and 264b on the peripheral of reflective surface 262. Micro-mirror assembly 256 further includes a set of stator electrodes 266a and 266b connected to electrode anchors 268a and 268b on semiconductor substrate 255. Electrode anchors 268a and 268b can be connected to terminals labelled “BIAS1” and “BIAS2,” whereas mirror anchors 260a and 260b can be connected to terminals labelled “COM.”

The set of rotor electrodes and stator electrodes can form an actuator, in which each set of electrodes can receive a control signal and generate a force (e.g., a magnetic force, an electrostatic force) against each other. In the example of FIG. 2E, stator electrodes 266a and rotor electrodes 264a can form a comb drive actuator 270a, whereas stator electrodes 266b and rotor electrodes 264b can form a comb drive actuator 270b. For example, when a voltage V1 is applied across rotor electrodes 264a and stator electrodes 266a (via COM and BIAS1 terminals), opposite charge can accumulate, and an electrostatic force F1, defined according to the following equation, can be developed between rotor electrodes 264a and stator electrodes 266a due to the accumulation of charges. With stator electrodes 266a and 266b fixed on semiconductor substrate 255, the force can create a torque that pushes rotor electrodes 264a and 264b away and causes micro-mirror 256 to rotate in one direction (e.g., a clock-wise direction).

F1=−P(V1)². (Equation 3)

In Equation 3, P is a constant based on permittivity, a number of fingers of the electrodes, gap between the electrodes, etc. As shown in Equation 3, the electrostatic force (and the resulting net torque) can be directly proportional to a square of applied voltage. The angle of rotation can be based on the torque as well as the spring stiffness of connection structures 258c and 258d, as described above in Equation 1. Moreover, when a voltage V2 is applied across rotor electrodes 264b and stator electrodes 266b, an electrostatic force F2 can develop according to Equation 3. Electrostatic force F2 can also apply a torque and cause micro-mirror 256 to rotate in another direction (e.g., a counter-clockwise direction). In some examples, a first AC voltage can be applied between the BIAS1 and COM terminals, whereas a second AC voltage can be applied between BIAS2 and COM terminals to rotate micro-mirror 256 following a scanning pattern as shown in FIG. 2C.

In some examples, a mapping table can be generated based on Equations 1-3 to provide a mapping between a target rotation angle θ and the control signal (e.g., voltages V1 and V2) supplied to the actuators. A controller can then refer to the mapping table to generate a control signal based on the target rotation angle and supply the control signal to control the rotation of micro-mirror 256 to rotate by the target rotation angle. In addition, the controller can supply the control signals at a frequency close to the natural frequency of micro-mirror 256 to induce harmonic resonance, which can substantially reduce the torque required to rotate the micro-mirror by the target rotation angle.

In some examples, micro-mirror assembly 252a can be fabricated from a SOI wafer having a first silicon substrate, an oxide layer, and a second silicon substrate, with the oxide layer sandwiched between the first silicon substrate and the second silicon substrate. Referring to the right of FIG. 2E, electrode anchors 268a and 268b as well as mirror anchors 260a and 260b can be fabricated from the first silicon substrate, which can be semiconductor substrate 255, and on an oxide layer 272, with a second silicon substrate 274 below oxide layer 272.

The performance of the light steering system, however, can be degraded by the limited control precision. Specifically, the controller can refer to the mapping table to generate a control signal for a given target rotation angle, but due to limited control precision, the actuator may be unable to rotate the mirror exactly by that target rotation angle. As a result, the mirror may be unable to rotate over a desired range of angle, which can reduce the achievable FOV. Moreover, due to the limited control precision, the rotation angles of each micro-mirror in the array also vary. The non-uniformity in the rotation angles of the micro-mirrors can increase the dispersion of the reflected light and reduce the imaging/ranging resolution.

The control precision limitation can come from various sources. One example source of control precision limitation comes from variations in the fabrication process. As described above, the torque required to rotate micro-mirror 256 by a target rotation angle depends on the spring constant of the connection structure. Due to variations in the fabrication process, the dimensions of the connection structure may become different from the designed values, which introduces variations in the spring constant of the connection structure. As a result, the torque required to rotate the micro-mirror by the target rotation angle may also be different from the value listed in the mapping table. As another example, the actuator may not create the target torque in response to the control signal due to various non-idealities. For example, due to electrical resistance of the transmission paths of the control signal, the amplitude of the control signal can be reduced when it arrives at the actuator. In all these cases, the actual rotation angle of the micro-mirror may not match the target rotation angle, which leads to degradation in the control precision of the micro-mirror.

### Examples of Adaptive Control Signal Generation

FIG. 3A illustrates an example of a light steering system 300 that can address at least some of the issues described above. Light steering system 300 can be implemented on a semiconductor substrate to form an integrated circuit. As shown in FIG. 3A, the light steering system comprises an actuator controller 301 and an array of micro-mirror assemblies 302. Each of array of micro-mirror assemblies 302 includes actuators 306, a micro-mirror 308, and terminals 310. Actuators 306 can include, for example, comb drive actuators 270a and 270b of FIG. 2E, micro-mirror 308 can include micro-mirror 256 of FIG. 2E, whereas terminals 310 can include the BIAS1, BIAS2, and COM terminals of FIG. 2E. Terminals 310 can receive control signals 311 (e.g., voltages) from actuator controller 301, and provide control signals 311 to actuators 306, which can set the rotation angle of the micro-mirror of the micro-mirror assembly based on the control signals.

Light steering system 300 further includes one or more measurement circuits 312, such as measurement circuit 312a. Each measurement circuit can measure an actual rotation angle of one or more micro-mirror assemblies. As to be described below, measurement circuits 312 can measure the actual rotation angle via measuring a capacitance of various components of the micro-mirror assembly. The measurement can be based on sending measurement signals 313 to terminals 310 of the micro-mirror assembly, and obtaining measurement results 314 via terminals 310. In some examples, the measurement circuit can measure the capacitance of a number of representative micro-mirror assemblies, and use the measurement results to estimate the actual rotation angle of the rest of the micro-mirror assemblies. In some examples, the measurement circuit can also measure the capacitance of each micro-mirror assembly within the array individually. Measurement circuits 312 can provide measurement results 314 to actuator controller 301.

In addition, actuator controller 301 includes measurement processing module 316 and a control signal generation module 320. Measurement processing module 316 can process the measurement results 314 to determine, for example, an actual rotation angle 318 of a particular micro-mirror assembly and differences among the rotation angles of multiple micro-mirror assemblies. Control signal generation module 320 can receive target rotation angle information 322 (e.g., from LiDAR controller 206) to generate control signal 311. The magnitude/frequency of control signal 311 can be determined based on a torque required to achieve the target rotation angle, and a property of the actuator that determines a relationship between the voltage and the torque, as described above in Equations 1-3. For example, control signal generation module 320 can maintain a mapping table 334 that maps different target rotation angles to different magnitudes/frequencies of control signal 332. From the mapping table, control signal generation module 320 can retrieve the magnitude/frequency of a control signal for target rotation angle 322 and generate control signal 332 according to the retrieved magnitude/frequency. Actuator controller 301 can then transmit control signal 311 to actuators 306 to rotate micro-mirror 308 by target rotation angle 322, which may or may not be the same as actual rotation angle 318 due to variations in the fabrication process of micro-mirror assembly 302, various non-idealities, etc., such that the actual relationship between the rotation angle and control signal is different from the mapping in mapping table 334. The difference between target rotation angle 322 and actual rotation angle 318 can represent a rotation angle error.

To reduce the rotation angle error, control signal adjustment module 340 can obtain actual rotation angle 318 and determine a relationship between actual rotation angle 318 and target rotation angle 322. Control signal adjustment module 340 can then adjust control signal 311 to generate control signal 321 based on the relationship. For example, control signal adjustment module 340 can generate control signal 321 based on adjusting the magnitude of control signal 311 as follows:

$${Signal}_{321} = \frac{Target rotation angle}{Actual rotation angle} \times {Signal}_{311} . \qquad ( Equation 4 )$$

In some examples, control signal generation module 320 can also generate control signal 321 based on a slow feedback mechanism, in which control signal generation module 320 increases or decreases the amplitude of control signal 311 in predetermined steps, and obtain the updated actual rotation angle from measurement circuits 312a for each step, until the rotation angle error settles to within an error threshold.

In some examples, control signal generation module 320 can generate control signal 332 having a particular frequency. The periodic rotation of micro-mirror 308 can be performed according to scanning pattern, as shown in FIG. 2C, to rotate micro-mirror 308 across a range of angles to achieve a two-dimensional FOV. Control signal 311 can be configured to inject energy into actuators 306 at a frequency close to a presumed natural frequency of micro-mirror 308 to induce harmonic resonance, which allows substantial reduction in the required torque to achieve a range of rotation for the target FOV. But the actual range of rotation angle may become smaller than the target range of rotation angle if the frequency of control signal 311 does not match the actual natural frequency of micro-mirror 308 due to the actual natural frequency of the micro-mirror being different from the presumed natural frequency. In such a case, adjustment module 340 can obtain measurements from measurement circuit 312a to determine the range of rotation angles of micro-mirror 308 in response to control signal 311. Adjustment module 340 can then generate control signal 321 based on increasing or decreasing the frequency of control signal 311d. The frequency of the control signal can be adjusted in steps until the actual range of rotation angles matches (to within an error threshold) a target range of rotation angles, which can indicate that the micro-mirror is being rotated at its natural frequency and harmonic resonance is achieved.

In some examples, adjustment module 340 can generate control signal 311 based on a comparison result between resistances of measurement structures of multiple micro-mirror assemblies. The comparison result can reflect differences among the actual rotation angles of the multiple micro-mirror assemblies at any given time. To ensure the rotations of the micro-mirrors are synchronized, adjustment module 340 can adjust control signal 311 to one or more micro-mirror assemblies to minimize the differences among the actual rotation angles of the multiple micro-mirror assemblies. For example, the comparison result may indicate that a first micro-mirror rotates by a larger angle than a second micro-mirror. Various adjustments can be made to the control signals based on the comparison result. In one example, adjustment module 340 can adjust the control signal (e.g., by reducing its amplitude and/or frequency) to the first micro-mirror to reduce its rotation angle to match the rotation angle of the second micro-mirror. In another example, adjustment module 340 can adjust the control signal to the second micro-mirror (e.g., by increasing its amplitude and/or frequency) to increase its rotation angle to match the rotation angle of the first micro-mirror. In yet another example, adjustment module 340 can adjust the control signal to the first micro-mirror to reduce the rotation angle of the first micro-mirror, and adjust the control signal to the second micro-mirror to increase the rotation angle of the second micro-mirror until the rotation angles of both micro-mirror reaches an average rotation angle.

As described above, measurement circuit 312a can measure the actual rotation angle of a micro-mirror assembly based on measuring the capacitances of various components of the micro-mirror assembly. FIG. 3B illustrates an example of capacitance measurement. Referring to FIG. 3B, measurement circuit 312a can measure the actual rotation angle based on measuring an electrode capacitance between a corresponding set of rotor electrodes 270 and stator electrodes 266. For example, measurement circuit 312a can measure an electrode capacitance between rotor electrodes 264a and stator electrodes 266a, an electrode capacitance between rotor electrodes 264b and stator electrodes 266b, etc. In FIG. 3B, electrode capacitance between rotor electrodes 264b and stator electrodes 266b is labelled as C_{BC}. A change in the electrode capacitance, labelled ΔC_{BC} in FIG. 3B, can reflect a change in overlapping area ΔA between the corresponding sets of electrodes, which in turn can reflect the rotation angle β of micro-mirror 254. In FIG. 3B, measurement circuit 312a can measure a capacitance C_{BC} between the Bias2 terminal and the COM terminal for the electrode capacitance between rotor electrodes 264b and stator electrodes 266b, and provide a measurement result of capacitance C_{BC} as part of measurement results 314 back to actuator controller 301. Measurement processing module 316 can then determine actual rotation angle 318 (β in FIG. 3B) based on the measurement result of capacitance C_{BC}.

The right of FIG. 3B illustrates a circuit model 342 including micro-mirror assembly 252a. Referring to circuit model 342, measurement circuit 312a can include a measurement signal generator 350 and a sensing circuit 352. Measurement signal generator 350 can apply a measurement voltage, which can be an AC voltage, at one of the terminals (e.g., BIAS2 or COM) to charge and discharge capacitance C_{BC} in each AC cycle. The measurement voltage can be superimposed on a control signal 311/321 supplied by actuator controller 301 (represented by a signal generator in FIG. 3B) across COM and BIAS2 terminals, and can have a much higher frequency than the control signal. For example, the measurement voltage can have a frequency in the megahertz (MHz) range, whereas the control signal can have a frequency in the kilohertz (KHz) range.

Sensing circuit 352 can measure the charging/discharging current (labelled i_{c}(t) in FIG. 3B) of capacitance C_{BC}, as well as a voltage across capacitance C_{BC} (labelled v_{c}(t) in FIG. 3B), between terminals BIAS2 and COM. Sensing circuit 352 can determine the reactance X_{C} of capacitance C_{BC} based on the following Equation:

$${X}_{C} = \frac{{v}_{c} ( t )}{i ( t )} = \frac{1}{2 π {fC}_{B C}} \qquad ( Equation 5 )$$

In Equation 5, f is the frequency of the measurement voltage. With reactance X_{C} and frequency f known, the capacitance C_{BC} can be determined. Measurement processing module 316 can then determine actual rotation angle 318 (β in FIG. 3B) based on capacitance C_{BC}.

In some examples, measurement circuits 312 can also measure the capacitance between stator electrodes 266a and rotor electrodes 264a (between Bias1 and COM terminals). The measured electrode capacitance between the Bias1 and COM terminals can be combined (e.g., averaged) with the measured electrode capacitance between the Bias2 and COM terminals, and the averaged capacitance can be provided to actuator controller 301 to determine actual rotation angle β.

In some examples, measurement circuits 312 can measure the actual rotation angle of a number of representative micro-mirror assemblies, and use the measurement results to estimate the actual rotation angle of the rest of the micro-mirror assemblies. For example, referring to FIG. 3C, light steering system 300 can include four measurement circuits 310a, 310b, 310c, and 310d each assigned to measure the electrode capacitance, respectively, corner micro-mirror assemblies 302a, 302b, 302c, and 302d. Each of corner micro-mirror assemblies 302a, 302b, 302c, and 302d can include the Bias1, Bias2, and COM terminals formed on semiconductor substrate 255. Each measurement circuit can measure an electrode capacitance between the Bias1 and COM terminals, an electrode capacitance between the Bias2 and Com terminals, or both. The electrode capacitances measured from each of corner micro-mirror assemblies 302a, 302b, 302c, and 302d can be averaged, and the averaged electrode capacitance can be used to determine the actual rotation angles of the rest of the micro-mirror assemblies. In some examples, one measurement circuit can be provided for each micro-mirror assembly to measure the electrode capacitance of each micro-mirror assembly individually, which allows actuator controller 301 to determine the actual rotation angle of each micro-mirror assembly individually, and adjust the control signal for each micro-mirror assembly individually.

The accuracy of the electrode capacitance measurement by measurement circuits 314, however, can be hindered by various parasitic capacitances in the semiconductor substrate. Referring to FIG. 3D, micro-mirror assembly 252a can have a parasitic capacitance C_{CS} formed between mirror anchors 260a/260b and silicon substrate 274, with oxide layer 272 acting as a dielectric. Moreover, micro-mirror assembly 252a can also have parasitic capacitances C_{BS1} and C_{BS2} formed between each of electrode anchors 268a and 268b and silicon substrate 274. Referring to the circuit model 342 of micro-mirror assembly 252a on the right of FIG. 3D, parasitic capacitances C_{CS} and C_{BS2} can add to the electrode capacitance C_{BC} between rotor electrodes 264b and stator electrodes 266b and can also be charged and discharged by the charging/discharging current from measurement signal generator 350. As the parasitic capacitances C_{CS} and C_{BS2} are largely static (e.g., determined based on the thickness of oxide layer 272) and do not change with the rotation angle of micro-mirror 256, the measured reactance can include an error component that do not reflect the rotation angle of the micro-mirror.

In addition, referring to FIG. 3E, some of the incident light received by micro-mirror assembly 252a, such as incident light 360a, can be reflected/steered by reflective surface 262, while some of the incident light, such as incident light 360b and 360c, can enter silicon substrate 274 at locations 364a and 364b via gaps between the stator and rotor electrodes. Incident light 360b and 360c can cause silicon substrate 274 to generate photocurrent. Referring to circuit model 342 on the right of FIG. 3E, micro-mirror assembly 252a can include one or more photocurrent sources, including photocurrent sources 370a and 370b representing, respectively, locations 364a and 364b silicon substrate 274 which generate the photocurrent from incident light 360b and 360c. Photocurrent sources 370a and 370b can deposit photo charge at the parasitic capacitances C_{CS} and C_{BS}. The photo charge the parasitic capacitances can introduce an error voltage component to vc(t) and/or an error current component to ic(t) which are not caused by measurement signal generator 350 and do not reflect the rotation angle of micro-mirror 256. As a result, the correspondence between the measured reactance (and capacitance) and the actual rotation angle is reduced. Given that actuator controller 301 may adjust the control signal to the actuators of the micro-mirror based on the measured capacitance, the error component in the measured capacitance can reduce the control precision of the micro-mirror by actuator controller 301.

### Examples Techniques to Reduce Photocurrent Generation

FIG. 4-FIG. 16B illustrate example techniques to reduce the effect of photocurrent on the electrode capacitance measurement. Referring to FIG. 4, micro-mirror assembly 252a can include one or more light reduction layers positioned below the stator and rotor electrodes. For example, micro-mirror assembly 252a can include a light reduction layer 400a positioned below rotor electrodes 264a and stator electrodes 266a, and a light reduction layer 400b positioned below rotor electrodes 264b and stator electrodes 266b. As to be described below, in some examples, light reduction layers 400a and 400b can be positioned between the electrodes and silicon substrate 274, or formed on a surface of silicon substrate 274 facing the electrodes, to reduce the amount of incident light (e.g., incident light 360b and 360c) that enters the semiconductor substrate, which can reduce the photocurrent generated by semiconductor substrate 274 and the resulting photo charge accumulated at the parasitic capacitances C_{CS}, C_{BS1}, and C_{BS2}. In some examples, light reduction layers 400a and 400b can also be formed within semiconductor substrate. The light reduction layer can prevent the incident light from entering regions of semiconductor substrate 274 that form the parasitic capacitances C_{CS}, C_{BS1}, and C_{BS2}, such as regions 402, 404, and 408, which can also reduce the photocurrent that flows into and charges the parasitic capacitances.

FIG. 5A and FIG. 5B illustrate an example of micro-mirror assembly 252a having a light reduction layer 500. As shown in FIG. 5A, light reduction layer 500 can cover at least a portion of oxide layer 272 and silicon substrate 274 below the gaps between rotor electrodes 264a and stator electrodes 266a, and below the gaps between rotor electrodes 264b and stator electrodes 266b. With such arrangements, light reduction layer 500 can block light from entering silicon substrate 274 via the gaps between the electrodes, or at least attenuate the light, to reduce the photocurrent generation at silicon substrate 274. In some examples, light reduction layer 500 can extend over oxide layer 272 and silicon substrate 274 so that light reduction layer 500 is between substrate semiconductor 255 and oxide layer 272.

In some examples, light reduction layer 500 can be part of a semiconductor layer between mirror anchors 260a/260b and oxide layer 272. Light reduction layer 500 can be fabricated as part of semiconductor substrate 255 that also include electrode anchors 268a/268b and mirror anchors 260a/260b. In some examples, semiconductor substrate 255 may further include additional electrode anchors, such as electrode anchors 502a and 502b, on light reduction layer 500, providing additional physical support to the stator electrodes. For example, stator electrodes 266a can be positioned on electrode anchors 268a and 502a, whereas stator electrodes 266b can be positioned on electrode anchors 268b and 502b.

In some examples, light reduction layer 500 can be connected to can be connected to a current sink (e.g., a voltage source) via terminals formed on semiconductor substrate 255 that are separate from the terminals for transmitting the control signals and measurement signals (e.g., COM, BIAS1, BIAS2, etc.) Light reduction layer 500 can absorb the incident light and convert the photons into photocurrent, which can be steered into the current sinks and away from the parasitic capacitances. FIG. 5B illustrates an example of light steering system 300 including micro-mirror assemblies having light reduction layer 500 and current sinks connected to light reduction layer 500. Referring to FIG. 5B, light steering system 300 can include four measurement circuits 310a, 310b, 310c, and 310d each assigned to measure the electrode capacitance, respectively, corner micro-mirror assemblies 502a, 502b, 502c, and 502d. Each of corner micro-mirror assemblies 502a, 502b, 502c, and 502d can include the Bias1, Bias2, and COM terminals formed on semiconductor substrate 255. Each measurement circuit can measure an electrode capacitance between the Bias1 and COM terminals, an electrode capacitance between the Bias2 and COM terminals, or both. In addition, each corner micro-mirror assembly further includes light reduction layer 500 of FIG. 5A as well as one or more LB terminals formed on semiconductor substrate 255 and connected to light reduction layer 500. Each LB terminal can be connected to a voltage source. For example, the LB terminals of corner micro-mirror assembly 302a are connected to voltage sources 504a and 504b, the LB terminals of corner micro-mirror assembly 302b are connected to voltage sources 504c and 504d, the corner micro-mirror assembly 302c are connected to voltage sources 504e and 504f, whereas the corner micro-mirror assembly 302d are connected to voltage sources 504g and 504h.

FIG. 6, FIG. 7A, and FIG. 7B illustrate an example fabrication process 600 for fabricating a micro-mirror assembly having light reduction layer 500. FIG. 6 illustrates the steps of fabrication process 600, whereas FIG. 7A and FIG. 7B illustrate a cross-sectional view of the micro-mirror assembly corresponding to steps of fabrication process 600.

Referring to FIG. 6, in step 602, a first silicon substrate of a SOI wafer is patterned to form a first region corresponding to electrode anchors and a second region corresponding to light reduction layer, the SOI wafer comprising the first silicon substrate, a second silicon substrate, and an oxide layer sandwiched between the first silicon substrate and the second silicon substrate.

Step 602 can include multiple sub-steps, including sub-steps 602a and 602b. Specifically, referring to FIG. 7A, in step 602a, an SOI wafer 700 comprising a first silicon substrate 701, an oxide layer 702, and a second silicon substrate 704 can be provided to fabricate the micro-mirror assembly. First silicon substrate 701 can correspond to semiconductor substrate 255 of FIG. 5A and include a MEMS device layer, oxide layer 702 can correspond to oxide layer 272 of FIG. 5A, whereas second silicon substrate 704 can correspond to semiconductor substrate 274 of FIG. 5A. A layer of photoresist 706 can be deposited on first silicon substrate 701. Photoresist layer 706 can be patterned (e.g., by lithography) into photoresist layers 706a, 706b, and 706c, with openings 710a and 710b. Opening 710a can separate between photoresist layers 706a and 706c, whereas opening 710b can separate between photoresist layers 706b and 706c. Photoresist layers 706a and 706b can cover first regions 712a and 712b of first silicon substrate 701 corresponding to electrode anchors, whereas photoresist layer 706c can cover second region 712c of first silicon substrate 701 corresponding to a light reduction layer.

In sub-step 602b, a first etching operation can be performed based on the patterned layer of photoresist 706. The first etching operation can include an anisotropic etching operation, such as a deep reactive-ion (DRIE) etching operation, to etch through first silicon substrate 701 at openings 710a and 710b to form trenches 714a and 714b. The etching operation can stop at oxide layer 702. At the end of the etching operation, first silicon substrate 701 can be patterned into regions 712a, 712b, and 712c on oxide layer 702.

Referring back to FIG. 6, in step 604, the second region of the first silicon substrate can be patterned to form mirror anchors and the light reduction layer, the mirror anchors being formed on the light reduction layer.

Step 604 can include multiple sub-steps, including sub-steps 604a and 604b. Specifically, referring to FIG. 7A, in step 604a, photoresist layer 706c on second region 712c of first silicon substrate 701 can be further patterned into photoresist layer 706e covering a region 712d corresponding to a mirror anchor. In some examples, photoresist layer 706c can be further patterned into photoresist layers 706f and 706g covering regions 712e and 712d corresponding to additional electrode anchors. Photoresist layers 706e and 706f can be separated by an opening 716a, whereas photoresist layers 706e and 706g can be separated by an opening 716b.

In sub-step 604b, a second etching operation can be performed on second region 712c of first silicon substrate 701 based on the patterned layer of photoresist 706c to form the mirror anchors and additional electrode anchors. The second etching operation can also include an anisotropic etching operation, such as a DRIE operation, at openings 716a and 716b to create cavities 718a and 718b. The etching operation can stop at a certain distance from oxide layer 702 to form light block layer 500 above oxide layer 702. The depth of cavities 718a and 718b can be based on, for example, a length of the micro-mirror (including the rotor electrodes) to be formed on the mirror anchors and a range of rotation of the micro-mirror, so that the cavities can accommodate the rotation of the micro-mirror. At the end of sub-step 604a, photoresist layers 706a, 70b, 706e, 706f, and 706g can be removed. Electrode anchors 722a and 722b can be formed on oxide layer 702, whereas electrode anchors 724a and 724b, as well as mirror anchors 726, can be formed on light reduction layer 500, which is formed on oxide layer 702.

Referring back to FIG. 6, in step 606, a silicon wafer can be bonded onto the electrode anchors and the mirror-anchors. Referring to FIG. 7B, a silicon wafer 730 can be positioned over and aligned with SOI wafer 700 having electrode anchors 722a, 722b, 724a, and 724b, as well as mirror anchors 726. A wafer bonding operation (e.g., direct bonding, thermal bonding) can be performed to bond silicon wafer 730 with electrode anchors 722a, 722b, 724a, and 724b, as well as mirror anchors 726.

Referring back to FIG. 6, in step 608, the silicon wafer can be patterned to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

Step 608 can include multiple sub-steps, including sub-steps 608a and 608b. Specifically, referring to FIG. 7B, in sub-step 608a, a layer of reflective material (e.g., metal) 732 can be formed on the silicon wafer 730 to form the reflective surface of the micro-mirror. Optionally (not shown in FIG. 7B), a layer of anti-reflective material (e.g., silicon nitride) can be formed on regions of silicon wafer 730 corresponding to rotor and stator electrodes. In sub-step 608b, a third etching operation, such as a DRIE operation, can be performed to pattern silicon wafer 730 into stator electrodes 734a and 734b, as well as a micro-mirror 736 that includes rotor electrodes 738a and 738b.

FIG. 8 illustrates another example of micro-mirror assembly 252a having a light reduction layer 800. As shown in FIG. 8, light reduction layer 800 can include a light reduction layer 800a formed on a surface of silicon substrate 274 below the gaps between rotor electrodes 264a and stator electrodes 266a, and a light reduction layer 800b below the gaps between rotor electrodes 264b and stator electrodes 266b. Light reduction layer 800 can be formed as a roughened surface of semiconductor substrate 274. The roughened surface can absorb the incident light via a recombination operation and convert the incident light into thermal energy. With such arrangements, light reduction layer 800 can prevent the incident light from entering semiconductor substrate 274, thereby reducing the photocurrent generated by the semiconductor substrate and the resulting photo charge accumulated at the parasitic capacitances between mirror anchors 260a/b and semiconductor substrate 274, and between electrode anchors 268a/b and semiconductor substrate 274.

FIG. 9, FIG. 10A, and FIG. 10B illustrate an example fabrication process 900 for fabricating a micro-mirror assembly having light reduction layer 500. FIG. 9 illustrates the steps of fabrication process 900, whereas FIG. 10A and FIG. 10B illustrate a cross-sectional view of a micro-mirror assembly corresponding to steps of fabrication process 600.

Referring to FIG. 9, in step 902, a first silicon substrate of a SOI wafer is patterned to form electrode anchors and mirror anchors, the SOI wafer comprising the first silicon substrate, a second silicon substrate, and an oxide layer sandwiched between the first silicon substrate and the second silicon substrate.

Step 902 can include multiple sub-steps, including sub-steps 902a and 902b. Specifically, referring to FIG. 10A, in sub-step 902a, an SOI wafer 1000 comprising a first silicon substrate 1001, an oxide layer 1002, and a second silicon substrate 1004 can be provided to fabricate the micro-mirror assembly. First silicon substrate 1001 can correspond to semiconductor substrate 255 of FIG. 8 and include a MEMS device layer, oxide layer 1002 can correspond to oxide layer 272 of FIG. 8, whereas second silicon substrate 1004 can correspond to semiconductor substrate 274 of FIG. 8. A layer of photoresist 1006 can be deposited on first silicon substrate 1001. Photoresist layer 1006 can be patterned (e.g., by lithography) into photoresist layers 1006a, 1006b, and 1006c, with openings 1010a and 1010b. Opening 1010a can separate between photoresist layers 1006a and 1006c, whereas opening 1010b can separate between photoresist layers 1006b and 1006c. Photoresist layers 1006a and 1006b can cover first regions 1012a and 1012b of first silicon substrate 1001 corresponding to electrode anchors, whereas photoresist layer 1006c can cover second region 1012c of first silicon substrate 1001 corresponding to mirror anchors.

In sub-step 1002b, a first etching operation can be performed based on the patterned layer of photoresist 1006. The first etching operations can include an anisotropic etching operation, such as a DRIE etching operation. The etching operation can stop at oxide layer 1002. At the end of the etching operation, first silicon substrate 1001 can be patterned into regions 1012a, 1012b, and 1012c on oxide layer 1002, as well as cavities 1014a between regions 1012a and 1012c and cavities 1014b between regions 1012c and 1012b.

Referring back to FIG. 9, in step 904, a part of oxide layer not covered by the electrode anchors and the mirror anchors is removed to expose a part of the second silicon substrate.

Specifically, referring to FIG. 10A, a second etching operation can be performed at cavities 1014a and 1014b to remove part of oxide layer 1002 outside of regions 1012a, 1012b, and 1012c of first silicon substrate 1001 to expose regions 1016a and 1016b of second silicon substrate 1004.

Referring back to FIG. 9, in step 906, a roughened surface on the part of the second silicon substrate can be formed, to form a light reduction layer.

Specifically, referring to FIG. 10A, a second etching operation can be performed on regions 1016a and 1016b of second silicon substrate 1004 to create the roughened surface. In some examples, the second etching operation can include a dry etching operation (e.g., a reactive-ion etching operation). Meanwhile, regions 1012a, 1012b, and 1012c of first silicon substrate 1001 can be protected from the dry etching operation by photoresist layers 1006a-c.

Referring back to FIG. 9, in step 908, a silicon wafer can be bonded onto the electrode anchors and the mirror-anchors. Referring to FIG. 10B, after the dry etching operation, photoresist layers 1006a-c can be removed, and regions 1012a, 1012b, and 1012c of first silicon substrate 1001 can form, respectively, electrode anchors 1022a/1022b and mirror anchors 1024. A silicon wafer 1030 can be positioned over and aligned with SOI wafer 1000 having electrode anchors 1022a/1022b and mirror anchors 1024. A wafer bonding operation (e.g., direct bonding, thermal bonding) can be performed to bond silicon wafer 1030 with electrode anchors 1022a/1022b and mirror anchors 1024.

Referring back to FIG. 9, in step 910, the silicon wafer can be patterned to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

Step 910 can include multiple sub-steps, including sub-steps 910a and 910b. Specifically, referring to FIG. 10B, in sub-step 910a, a layer of reflective material (e.g., metal) 1032 can be formed on the silicon wafer 1030 to form the reflective surface of the micro-mirror. Optionally (not shown in FIG. 10B), a layer of anti-reflective material (e.g., silicon nitride) can be formed on regions of silicon wafer 1030 corresponding to rotor and stator electrodes. In sub-step 910b, a third etching operation, such as a DRIE operation, can be performed to pattern silicon wafer 1030 into stator electrodes 1034a and 1034b, as well as a micro-mirror 1036 that includes rotor electrodes 1038a and 1038b.

In some examples, the second etching operation described in step 906 can be performed after step 910 such that the light reduction layers 800a and 800b are formed only underneath the gaps between the stator electrodes and rotor electrodes.

FIG. 11 illustrates an example of micro-mirror assembly 252a having a stacked light reduction layer 1100. A stacked light reduction layer 1100 can include a reflective layer (e.g., a metal layer, an oxide layer, etc.) sandwiched between two insulator layers. As shown in FIG. 11, a stacked light reduction layer 1100 can include a stacked light reduction layer 1100a formed on a surface of silicon substrate 274 below the gaps between rotor electrodes 264a and stator electrodes 266a, and a stacked light reduction layer 1100b below the gaps between rotor electrodes 264b and stator electrodes 266b. The reflective layer in stacked light reduction layer 1100 can reflect incident light away from semiconductor substrate 274 and prevent the light from entering the semiconductor substrate.

FIG. 12, FIG. 13A, and FIG. 13B illustrate an example fabrication process 1200 for fabricating a micro-mirror assembly having stacked light reduction layer 1100. FIG. 12 illustrates the steps of fabrication process 900, whereas FIG. 13A and FIG. 13B illustrate a cross-sectional view of a micro-mirror assembly corresponding to steps of fabrication process 200.

Referring to FIG. 12, in step 1202, a first silicon substrate of a SOI wafer is patterned to form electrode anchors and mirror anchors, the SOI wafer comprising the first silicon substrate, a second silicon substrate, and an oxide layer sandwiched between the first silicon substrate and the second silicon substrate.

Step 1202 can include multiple sub-steps, including sub-steps 1202a and 1202b. Specifically, referring to FIG. 13A, in sub-step 1202a, an SOI wafer 1300 comprising a first silicon substrate 1301, an oxide layer 1302, and a second silicon substrate 1304 can be provided to fabricate the micro-mirror assembly. First silicon substrate 1301 can correspond to semiconductor substrate 255 of FIG. 11 and include a MEMS device layer, oxide layer 1302 can correspond to oxide layer 272 of FIG. 11, whereas second silicon substrate 1304 can correspond to semiconductor substrate 274 of FIG. 11. A layer of photoresist 1306 can be deposited on first silicon substrate 1301. Photoresist layer 1306 can be patterned (e.g., by lithography) into photoresist layers 1306a, 1306b, and 1306c, with openings 1310a and 1310b. Opening 1310a can separate between photoresist layers 1306a and 1306c, whereas opening 1310b can separate between photoresist layers 1306b and 1306c. Photoresist layers 1306a and 1306b can cover first regions 1312a and 1312b of first silicon substrate 1301 corresponding to electrode anchors, whereas photoresist layer 1306c can cover second region 1312c of first silicon substrate 1301 corresponding to mirror anchors.

In sub-step 1202b, a first etching operation can be performed based on the patterned layer of photoresist 1306. The first etching operations can include an anisotropic etching operation, such as a DRIE etching operation. The etching operation can stop at oxide layer 1302. At the end of the etching operation, first silicon substrate 1301 can be patterned into regions 1312a, 1312b, and 1312c on oxide layer 1302, as well as cavities 1314a between regions 1312a and 1312c and cavities 1314b between regions 1312c and 1312b.

Referring back to FIG. 11, in step 1104, a part of oxide layer not covered by the electrode anchors and the mirror anchors is removed to expose a part of the second silicon substrate.

Specifically, referring to FIG. 13A, a second etching operation can be performed at cavities 1314a and 1314b to remove part of oxide layer 1302 outside of regions 1312a, 1312b, and 1312c of first silicon substrate 1301 to expose regions 1316a and 1316b of second silicon substrate 1304.

Referring back to FIG. 12, in step 1206, a stacked light reduction layer can be formed on the part of the second silicon substrate. The stacked light block blocking layer can include a reflective layer, such as a metal layer, sandwiched between two insulator layers.

Specifically, referring to FIG. 13A, a film deposition operation (e.g., a physical vapor deposition operation) can be performed to deposit multiple layers of films, as stacked light reduction layer 1100, over expose regions 1316a and 1316b of second silicon substrate 1304, as well as over photoresist layers 1306a, 1306b, and 1306c. For example, stacked light reduction layers 1100a and 1100b are deposited on regions 1316a and 1316b of second silicon substrate 1304, whereas stacked light reduction layers 1100c, 1100d, and 1100e are deposited on, respectively photoresist layers 1306a, 1306b, and 1306c.

Referring back to FIG. 12, in step 1208, a silicon wafer can be bonded onto the electrode anchors and the mirror-anchors. Referring to FIG. 13B, after the film deposition operation is performed, stacked light reduction layers 1100c, 1100d, and 1100e can be removed in a lift-off process in which the photoresist layers 1306a, 1306b, and 1306c are removed from, respectively, regions 1312a, 1312b, and 1312c, leaving behind stacked light reduction layers 1100a and 1100b on regions 1316a and 1316b of second silicon substrate 1304. Regions 1312a, 1312b, and 1312c of first silicon substrate 1301 can then form, respectively, electrode anchors 1322a/1322b and mirror anchors 1324. A silicon wafer 1330 can be positioned over and aligned with SOI wafer 1300 having electrode anchors 1322a/1322b and mirror anchors 1324. A wafer bonding operation (e.g., direct bonding, thermal bonding, etc.) can be performed to bond silicon wafer 1330 with electrode anchors 1322a/1322b and mirror anchors 1324.

Referring back to FIG. 12, in step 1210, the silicon wafer can be patterned to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

Step 1210 can include multiple sub-steps, including sub-steps 1210a and 1210b. Specifically, referring to FIG. 13B, in sub-step 1210a, a layer of reflective material (e.g., metal) 1332 can be formed on the silicon wafer 1330 to form the reflective surface of the micro-mirror. Optionally (not shown in FIG. 13B), a layer of anti-reflective material (e.g., silicon nitride) can be formed on regions of silicon wafer 1330 corresponding to rotor and stator electrodes. In sub-step 1210b, a second etching operation, such as a DRIE operation, can be performed to pattern silicon wafer 1330 into stator electrodes 1334a and 1334b, as well as a micro-mirror 1336 that includes rotor electrodes 1338a and 1338b.

FIG. 14 illustrates an example of micro-mirror assembly 252a having a light reduction layer 1400 formed below a surface of semiconductor substrate 274. As shown in FIG. 14, a light reduction layer 1400a can be formed below a surface of silicon substrate 274 below the gaps between rotor electrodes 264a and stator electrodes 266a, whereas a light reduction layer 1400b can be formed below a surface of silicon substrate 274 below the gaps between rotor electrodes 264b and stator electrodes 266b. Both light reduction layers 1400a and 1400b can absorb incident light and prevent the light from entering parts of the semiconductor substrate below mirror anchors 260a/b and electrode anchors 268a/b, such as regions 402, 404, and 408, which can also reduce the photocurrent that flows into and charges the parasitic capacitances C_{CS}, C_{BS1}, and C_{BS2}. Although FIG. 14 shows that there is no oxide layer 272 above light reduction layers 1400a and 1400b, it is understood that in some examples light reduction layers 1400a and 1400b can also be formed below oxide layer 272.

In some examples, light reduction layers 1400a and 1400b can have a higher concentration of charge carriers than parts of semiconductor substrate 274 that form the parasitic capacitances, such as regions 402, 404, and 408. The higher concentration of charge carriers can be caused by, for example, light reduction layer 1400 being more heavily doped than regions 402, 404, and 408 of semiconductor substrate 274. Such arrangements allow the photo charge generated by light reduction layers 1400a and 1400b to quickly recombine with the charge carriers, which can prevent the photo charge from flowing into the parasitic capacitances C_{CS}, C_{BS1}, and C_{BS2}.

FIG. 15, FIG. 16A, and FIG. 16B illustrate an example fabrication process 1500 for fabricating a micro-mirror assembly having light reduction layer 1400. FIG. 15 illustrates the steps of fabrication process 1500, whereas FIG. 16A and FIG. 16B illustrate a cross-sectional view of a micro-mirror assembly corresponding to steps of fabrication process 600.

Referring to FIG. 15, in step 1502, a first silicon substrate of a SOI wafer is patterned to form electrode anchors and mirror anchors, the SOI wafer comprising the first silicon substrate, a second silicon substrate, and an oxide layer sandwiched between the first silicon substrate and the second silicon substrate.

Step 1502 can include multiple sub-steps, including sub-steps 1502a and 1502b. Specifically, referring to FIG. 16A, in sub-step 1502a, an SOI wafer 1600 comprising a first silicon substrate 1601, an oxide layer 1602, and a second silicon substrate 1604 can be provided to fabricate the micro-mirror assembly. First silicon substrate 1601 can correspond to semiconductor substrate 255 of FIG. 8 and include a MEMS device layer, oxide layer 1602 can correspond to oxide layer 272 of FIG. 8, whereas second silicon substrate 1004 can correspond to semiconductor substrate 274 of FIG. 8. A layer of photoresist 1606 can be deposited on first silicon substrate 1601. Photoresist layer 1606 can be patterned (e.g., by lithography) into photoresist layers 1606a, 1606b, and 1606c, with openings 1610a and 1610b. Opening 1610a can separate between photoresist layers 1606a and 1606c, whereas opening 1610b can separate between photoresist layers 1606b and 1606c. Photoresist layers 1606a and 1606b can cover first regions 1612a and 1612b of first silicon substrate 1001 corresponding to electrode anchors, whereas photoresist layer 1606c can cover second region 1612c of first silicon substrate 1601 corresponding to mirror anchors.

In sub-step 1602b, a first etching operation can be performed based on the patterned layer of photoresist 1006. The first etching operations can include an anisotropic etching operation, such as a DRIE etching operation. The etching operation can stop at oxide layer 1602. At the end of the etching operation, first silicon substrate 1601 can be patterned into regions 1612a, 1612b, and 1612c on oxide layer 1602, as well as cavities 1614a between regions 1612a and 1612c and cavities 1614b between regions 1612c and 1612b.

Referring back to FIG. 15, in step 1504, a part of oxide layer not covered by the electrode anchors and the mirror anchors is removed to expose a part of the second silicon substrate.

Specifically, referring to FIG. 16A, a second etching operation can be performed at cavities 1614a and 1614b to remove part of oxide layer 1002 outside of regions 1612a, 1612b, and 1612c of first silicon substrate 1601 to expose regions 1616a and 1616b of second silicon substrate 1604.

Referring back to FIG. 15, in step 1506, a light reduction layer can be formed under a surface of the part of second silicon substrate.

Specifically, referring to FIG. 16A, an ion implantation operation can be performed on regions 1616a and 1616b of second silicon substrate 1604 to light reduction layers 1400a and 1400b within second silicon substrate 1604. Meanwhile, regions 1612a, 1612b, and 1612c of first silicon substrate 1601, as well as part of second silicon substrate 1604 under these regions, can be shielded from the ion implantation operation by photoresist layers 1606a-c.

Referring back to FIG. 15, in step 1508, a silicon wafer can be bonded onto the electrode anchors and the mirror-anchors. Referring to FIG. 16B, after the ion implantation operation, photoresist layers 1606a-c can be removed, and regions 1612a, 1612b, and 1612c of first silicon substrate 1601 can form, respectively, electrode anchors 1622a/1622b and mirror anchors 1624. A silicon wafer 1630 can be positioned over and aligned with SOI wafer 1600 having electrode anchors 1622a/1622b and mirror anchors 1624. A wafer bonding operation (e.g., direct bonding, thermal bonding.) can be performed to bond silicon wafer 1630 with electrode anchors 1622a/1622b and mirror anchors 1624.

Referring back to FIG. 15, in step 1510, the silicon wafer can be patterned to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

Step 1510 can include multiple sub-steps, including sub-steps 1510a and 1510b. Specifically, referring to FIG. 16B, in sub-step 1510a, a layer of reflective material (e.g., metal) 1032 can be formed on the silicon wafer 1530 to form the reflective surface of the micro-mirror. Optionally (not shown in FIG. 16B), a layer of anti-reflective material (e.g., silicon nitride) can be formed on regions of silicon wafer 1530 corresponding to rotor and stator electrodes. In sub-step 1510b, a third etching operation, such as a DRIE operation, can be performed to pattern silicon wafer 1530 into stator electrodes 1534a and 1534b, as well as a micro-mirror 1536 that includes rotor electrodes 1538a and 1538b.

In some examples, the ion implantation operation described in step 1506 can be performed after step 1510 such that light reduction layers 1400a and 1400b are formed only underneath the gaps between the stator electrodes and rotor electrodes.

Any of the methods described herein may be totally or partially performed with a computer system including one or more processors, which can be configured to perform the steps. Thus, embodiments can be directed to computer systems configured to perform the steps of any of the methods described herein, potentially with different components performing a respective steps or a respective group of steps. Although presented as numbered steps, steps of methods herein can be performed at a same time or in a different order. Additionally, portions of these steps may be used with portions of other steps from other methods. Also, all or portions of a step may be optional. Additionally, any of the steps of any of the methods can be performed with modules, units, circuits, or other means for performing these steps.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions, and equivalents falling within the spirit and scope of the disclosure, as defined in the appended claims. For instance, any of the embodiments, alternative embodiments, etc., and the concepts thereof may be applied to any other embodiments described and/or within the spirit and scope of the disclosure.

The use of the terms “a,” “an,” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning including, but not limited to) unless otherwise noted. The term “connected” is to be construed as partly or wholly contained within, attached to, or joined together, even if there is something intervening. The phrase “based on” should be understood to be open-ended and not limiting in any way and is intended to be interpreted or otherwise read as “based at least in part on,” where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

What is claimed is:

1. An apparatus comprising a light detection and ranging (LiDAR) module, the LiDAR module comprising:
a semiconductor integrated circuit, the semiconductor integrated circuit including a microelectromechanical system (MEMS) device layer and a silicon substrate, the MEMS device layer including at least one micro-mirror assembly, the at least one micro-mirror assembly including:
a micro-mirror comprising a reflective surface, the micro-mirror being coupled with mirror anchors on the silicon substrate at a pair of pivot points, the reflective surface being configured to reflect incident light; and
electrodes coupled with electrode anchors on the silicon substrate and controllable to rotate the micro-mirror around the pair of pivot points to set a direction of reflection of the incident light by the reflective surface,
wherein the at least one micro-mirror assembly includes a light reduction layer formed below a surface of the silicon substrate.

2. The apparatus of claim 1, wherein the light reduction layer has a higher dopant concentration than a part of the silicon substrate around and below the light reduction layer.

3. The apparatus of claim 2, wherein the light reduction layer is doped with an N-type or a P-type dopant; and
wherein the rest of the silicon substrate is not doped with any dopant.

4. The apparatus of claim 2, wherein both the light reduction layer and the rest of the silicon substrate are doped with an N-type or a P-type dopant.

5. The apparatus of claim 1, wherein the light reduction layer is below gaps between the micro-mirror and the electrodes.

6. The apparatus of claim 1, further comprising an oxide layer sandwiched between each of the mirror anchors and electrode anchors and the silicon substrate.

7. The apparatus of claim 6, wherein the oxide layer is also sandwiched between each of the mirror anchors and electrode anchors and the light reduction layer.

8. The apparatus of claim 1, wherein the electrodes comprise first rotary electrodes and second rotary electrodes of the micro-mirror, and first stator electrodes and second stator electrodes formed on the electrode anchors;
wherein the first rotary electrodes interdigitate with the first stator electrodes to form a first actuator; and
wherein the second rotary electrodes interdigitate with the second stator electrodes to form a second actuator.

9. The apparatus of claim 8, further comprising a measurement circuit configured to:
apply a first voltage at the first stator electrodes;
measure a second voltage between the first stator electrodes and the first rotary electrodes; and
determine an actual angle of rotation of the micro-mirror based on the second voltage;
wherein the second voltage is based on the first voltage, a first capacitance between the first stator electrodes and the first rotary electrodes, a second capacitance between the mirror anchors and the silicon substrate, and a third capacitance between the first stator electrodes and the silicon substrate; and
wherein the light reduction layer is configured to reduce a quantity of charge generated by the silicon substrate in response to receiving the at least part of the incident light and accumulated at the second capacitance and the third capacitance.

10. The apparatus of claim 8, further comprising a controller configured to:
apply a third voltage between the first stator electrodes and the first rotary electrodes, and a fourth voltage between the second stator electrodes and the second rotary electrodes, to rotate the micro-mirror by a target rotation angle;
determine a difference between the target rotation angle and the actual rotation angle; and
adjust the third and fourth voltages based on the difference;
wherein the first voltage comprises an AC voltage at a first frequency;
wherein the third and fourth voltages comprise AC voltages at a second frequency; and
wherein the second frequency is lower than the first frequency.

11. The apparatus of claim 10, wherein the MEMS device layer comprises an array of micro-mirror assemblies; and
wherein the controller is configured to generate a voltage for the electrodes of a second micro-mirror assembly of the array of micro-mirror assemblies based on the actual rotation angle of the micro-mirror of the at least one micro-mirror assembly.

12. A method of fabricating a micro-mirror assembly of a Light Detection and Ranging (LiDAR) module, comprising:
patterning a first silicon substrate of a silicon-on-insulator (SOI) wafer to form electrode anchors and mirror anchors, the SOI wafer comprising a first silicon substrate, a second silicon substrate, and an oxide layer sandwiched between the first silicon substrate and the second silicon substrate, the electrode anchors and mirror anchors being formed on the oxide layer;
removing a part of the oxide layer not covered by the electrode anchors and mirror anchors to expose a part of the second silicon substrate;
forming a light reduction layer below a surface of the exposed part of the second silicon substrate;
bonding a silicon wafer onto the electrode anchors and the mirror anchors; and
patterning the silicon wafer to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.

13. The method of claim 12, wherein the light reduction layer is formed based on performing an ion implantation operation on the part of the second silicon substrate to form the light reduction layer below the surface of the part of the second silicon substrate.

14. The method of claim 13, further comprising:
covering the first silicon substrate with a layer of photoresist;
patterning the layer of photoresist to form a patterned layer of photoresist that covers regions of the first silicon substrate corresponding to the mirror anchors and the electrode anchors; and
after the first silicon substrate is patterned according to the patterned layer of photoresist, performing the ion implantation operation.

15. The method of claim 14, wherein the ion implantation operation is performed after the silicon wafer is patterned to form the light reduction layer under gaps between the micro-mirror and the electrodes.

16. The method of claim 14, wherein the first silicon substrate is patterned, based on the patterned layer of photoresist, using a first deep reactive-ion (DRIE) etching process that stops at the oxide layer, followed by an oxide etching process to remove the part of the oxide layer.

17. The method of claim 12, wherein the silicon wafer is bonded onto the electrode anchors and the mirror anchors via a wafer-bonding operation.

18. The method of claim 12, wherein:
the electrodes include first stator electrodes and second stator electrodes coupled with the electrode anchors;
the micro-mirror further includes first rotary electrodes and second stator electrodes;
the first rotary electrodes interdigitate with the first stator electrodes to form a first actuator;
the second rotary electrodes interdigitate with the second stator electrodes to form a second actuator;
the method further comprises:
coating a layer of metal over a first part of the micro-mirror to form a reflective surface; and
coating a layer of anti-reflection material over a second part of the micro-mirror corresponding to the first rotary electrodes and the second rotary electrodes and over the first and second stator electrodes.

19. The method of claim 18, further comprising:
after coating the layer of metal and the layer of anti-reflection material, performing a third DRIE etching process to form the micro-mirror and the first and second stator electrodes.

20. A micro-mirror assembly fabricated by a process comprising:
patterning a first silicon substrate of a silicon-on-insulator (SOI) wafer to form electrode anchors and mirror anchors, the SOI wafer comprising a first silicon substrate, a second silicon substrate, and an oxide layer sandwiched between the first silicon substrate and the second silicon substrate, the electrode anchors and mirror anchors being formed on the oxide layer;
removing a part of the oxide layer not covered by the electrode anchors and mirror anchors to expose a part of the second silicon substrate;
forming a light reduction layer below a surface of the part of the second silicon substrate;
bonding a silicon wafer onto the electrode anchors and the mirror anchors; and
patterning the silicon wafer to form a micro-mirror and electrodes of the micro-mirror assembly on, respectively, the mirror anchors and the electrode anchors, the micro-mirror being coupled with the mirror anchors at a pair of pivot points, the electrodes being controllable to rotate the micro-mirror around the pair of pivot points.
